(19) United States
(12) Patent Application Publication
(10) Pub. No.: US 2025/0023321 A1
(43) Pub. Date: Jan. 16, 2025

(54) SEMICONDUCTOR LIGHT EMITTING DEVICE

(71) Applicant: ROHM CO., LTD., Kyoto (JP)

(72) Inventors: Yoshinori TANAKA, Kyoto (JP); Akito SHINODA, Kyoto (JP)

(21) Appl. No.: 18/765,448

(22) Filed: Jul. 8, 2024

(30) Foreign Application Priority Data
Jul. 13, 2023 (JP) 2023-115337

(51) Int. Cl. H01S 5/023; H01S 5/0683

(52) U.S. Cl. CPC H01S 5/023; H01S 5/0683

(57) ABSTRACT

A semiconductor light emitting device includes: a substrate including a substrate front surface; an edge light emitting element mounted on the substrate front surface, the edge light emitting element including a first element end surface facing a first direction intersecting a thickness direction perpendicular to the substrate front surface and a second element end surface facing an opposite direction to the first element end surface, the edge light emitting element configured such that light is emitted from the first element end surface and the second element end surface; a light receiving sub-mount provided over the substrate front surface and including a mounting surface facing the second element end surface; and a light receiving element mounted on the mounting surface and including a light receiving portion provided at a light receiving element front surface and facing the second element end surface.

### CROSS-REFERENCE TO RELATED APPLICATION

This application is based upon and claims the benefit of priority from Japanese Patent Application No. 2023-115337, filed on Jul. 13, 2023, the entire contents of which are incorporated herein by reference.

### TECHNICAL FIELD

The present disclosure relates to a semiconductor light emitting device.

### BACKGROUND

A semiconductor light emitting device provided with light emitting diodes as light sources is known in the related art.

### BRIEF DESCRIPTION OF DRAWINGS

The accompanying drawings, which are incorporated in and constitute a part of the specification, illustrate embodiments of the present disclosure.

FIG. 1 is a schematic plan view of a semiconductor light emitting device according to a first embodiment.

FIG. 2 is a schematic cross-sectional view of the semiconductor light emitting device taken along line 2-2 in FIG. 1.

FIG. 3 is a schematic rear view of the semiconductor light emitting device shown in FIG. 1.

FIG. 4 is a schematic cross-sectional view of the semiconductor light emitting device taken along line 4-4 in FIG. 2.

FIG. 5 is a schematic plan view of a semiconductor light emitting device according to a second embodiment.

FIG. 6 is a schematic cross-sectional view of the semiconductor light emitting device taken along line 6-6 in FIG. 5.

FIG. 7 is a schematic plan view of a semiconductor light emitting device according to a third embodiment.

FIG. 8 is a schematic cross-sectional view of the semiconductor light emitting device taken along line 8-8 in FIG. 7.

FIG. 9 is a schematic rear view of the semiconductor light emitting device shown in FIG. 7.

FIG. 10 is a schematic cross-sectional view of the semiconductor light emitting device taken along line 10-10 in FIG. 7.

FIG. 11 is a schematic plan view of a semiconductor light emitting device according to a fourth embodiment.

FIG. 12 is a schematic cross-sectional view of the semiconductor light emitting device taken along line 12-12 in FIG. 11.

FIG. 13 is a schematic plan view of a semiconductor light emitting device according to a fifth embodiment.

FIG. 14 is a schematic cross-sectional view of the semiconductor light emitting device taken along line 14-14 in FIG. 13.

FIG. 15 is a schematic rear view of the semiconductor light emitting device shown in FIG. 13.

FIG. 16 is a schematic plan view of a semiconductor light emitting device according to a sixth embodiment.

FIG. 17 is a schematic cross-sectional view of the semiconductor light emitting device taken along line 17-17 in FIG. 16.

FIG. 18 is a schematic cross-sectional view of a semiconductor light emitting device according to a seventh embodiment.

FIG. 19 is a schematic cross-sectional view of the semiconductor light emitting device taken along line 19-19 in FIG. 18.

FIG. 20 is a schematic cross-sectional view of a semiconductor light emitting device according to an eighth embodiment.

FIG. 21 is a schematic cross-sectional view of the semiconductor light emitting device taken along line 21-21 in FIG. 20.

FIG. 22 is a schematic cross-sectional view of a semiconductor light emitting device according to a ninth embodiment.

FIG. 23 is a schematic cross-sectional view of the semiconductor light emitting device taken along line 23-23 in FIG. 22.

FIG. 24 is a schematic cross-sectional view of a semiconductor light emitting device according to a modification.

FIG. 25 is a schematic cross-sectional view of a semiconductor light emitting device according to a modification.

FIG. 26 is a schematic plan view of a semiconductor light emitting device according to a modification.

FIG. 27 is a schematic cross-sectional view of the semiconductor light emitting device taken along line 27-27 in FIG. 26.

FIG. 28 is a schematic plan view of a semiconductor light emitting device according to a modification.

FIG. 29 is a schematic cross-sectional view of the semiconductor light emitting device taken along line 29-29 in FIG. 28.

FIG. 30 is a schematic plan view of a semiconductor light emitting device according to a modification.

FIG. 31 is a schematic cross-sectional view of the semiconductor light emitting device taken along line 31-31 in FIG. 30.

FIG. 32 is a schematic plan view of a semiconductor light emitting device according to a modification.

FIG. 33 is a schematic cross-sectional view of the semiconductor light emitting device taken along line 33-33 in FIG. 32.

FIG. 34 is a schematic cross-sectional view of a semiconductor light emitting device according to a modification.

FIG. 35 is a schematic cross-sectional view of a semiconductor light emitting device according to a modification.

FIG. 36 is a schematic plan view of a semiconductor light emitting device according to a tenth embodiment.

FIG. 37 is a schematic cross-sectional view of the semiconductor light emitting device taken along line 37-37 in FIG. 36.

FIG. 38 is a schematic rear view of the semiconductor light emitting device shown in FIG. 36.

FIG. 39 is a schematic plan view of a semiconductor light emitting device according to an eleventh embodiment.

FIG. 40 is a schematic cross-sectional view of the semiconductor light emitting device taken along line 40-40 in FIG. 39.

FIG. 41 is a schematic rear view of the semiconductor light emitting device shown in FIG. 39.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, some embodiments of the semiconductor light emitting device of the present disclosure are described with reference to the accompanying drawings. For simplicity and clarity of description, the components shown in the drawings are not necessarily drawn on a constant scale. Further, in order to facilitate understanding, hatching lines may be omitted in cross-sectional views. The accompanying drawings are merely illustrative of embodiments of the present disclosure and should not be considered as limiting the present disclosure.

The following detailed description includes an apparatus, a system and a method that embody exemplary embodiments of the present disclosure. This detailed description is exemplary in nature and is not intended to limit the embodiments of the present disclosure or the applications and uses of such embodiments.

### First Embodiment

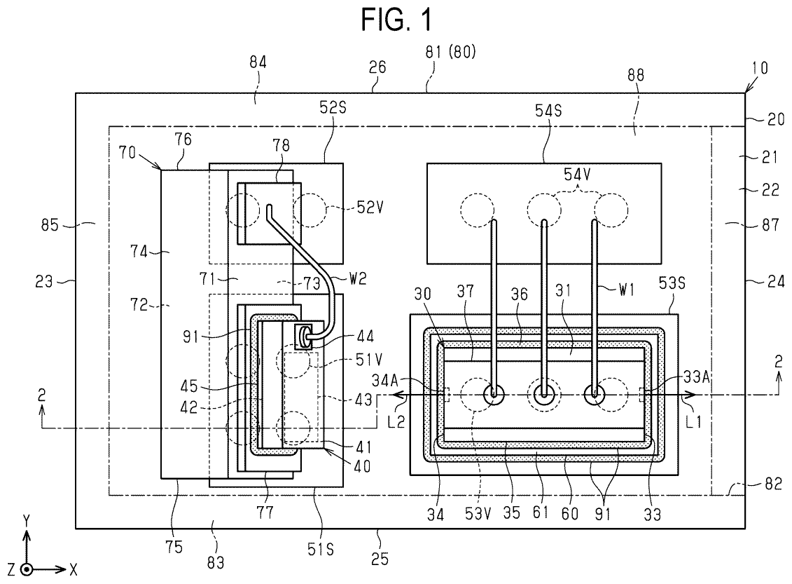

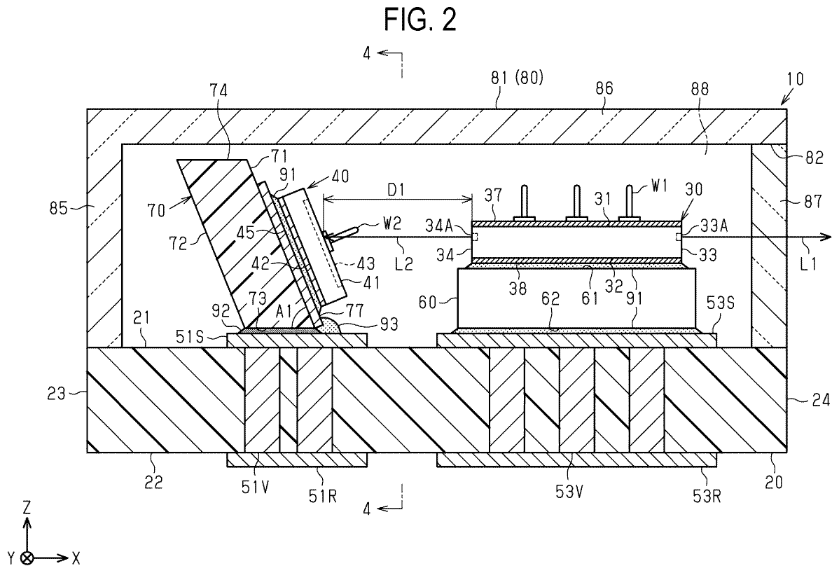

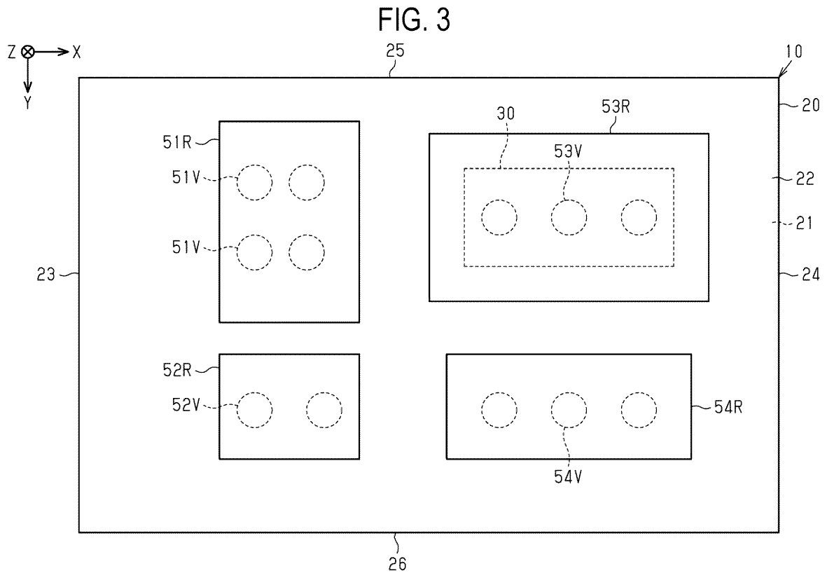

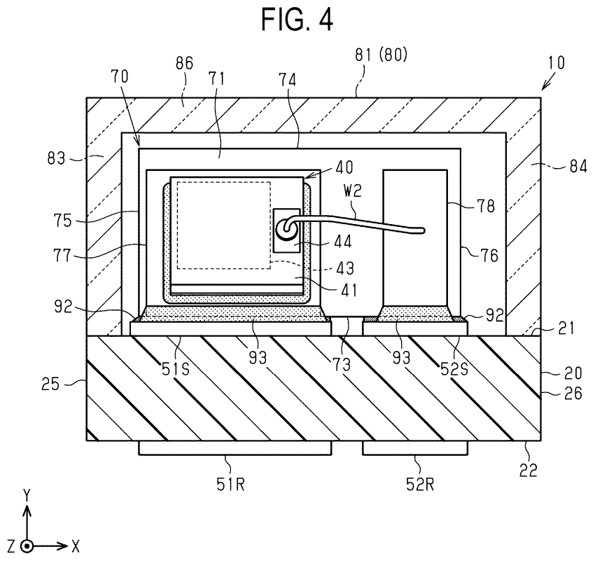

A semiconductor light emitting device 10 according to a first embodiment is described with reference to FIGS. 1 to 4. FIG. 1 is a schematic plan view of the semiconductor light emitting device 10 according to the first embodiment. FIG. 2 is a schematic cross-sectional view of the semiconductor light emitting device 10 taken along line 2-2 in FIG. 1. FIG. 3 is a schematic rear view of the semiconductor light emitting device 10 shown in FIG. 1. FIG. 4 is a schematic cross-sectional view of the semiconductor light emitting device 10 taken along line 4-4 in FIG. 2. The term “plan view” used in the present disclosure refers to viewing an object in a Z direction of mutually orthogonal XYZ axes shown in FIG. 1, for example.

### Schematic Configuration of Semiconductor Light Emitting Device

As shown in FIGS. 1 and 2, the semiconductor light emitting device 10 includes a substrate 20, an edge light emitting element 30 disposed on the substrate 20, and a light receiving element 40 disposed on the substrate 20. The semiconductor light emitting device 10 includes a light receiving sub-mount 70 on which the light receiving element 40 is mounted. The semiconductor light emitting device 10 may include a light emitting sub-mount 60 on which the edge light emitting element 30 is mounted. Further, the semiconductor light emitting device 10 may include a cover member 80 that accommodates at least a portion of the edge light emitting element 30 and at least a portion of the light receiving element 40.

### Substrate

The substrate 20 is a component that supports the edge light emitting element 30 and the light receiving element 40. The substrate 20 is formed into a rectangular flat plate shape with the Z direction being the thickness direction thereof.

The substrate 20 is formed into a rectangular shape with the length thereof in the Y direction being shorter than the length thereof in the X direction in a plan view. The substrate 20 includes a substrate front surface 21, a substrate back surface 22 opposite to the substrate front surface 21 in the Z direction, and first to fourth substrate side surfaces 23 to 26 that connect the substrate front surface 21 and the substrate back surface 22. The first substrate side surface 23 and the second substrate side surface 24 constitute both end surfaces of the substrate 20 in the X direction, and the third substrate side surface 25 and the fourth substrate side surface 26 constitute both end surfaces of the substrate 20 in the Y direction. The shape of the substrate 20 in a plan view may be arbitrarily changed.

The substrate 20 is formed of, for example, an insulating material. The substrate 20 may be formed of, for example, a resin material containing an epoxy resin. The resin material may contain a filler such as glass or ceramics. Furthermore, the substrate 20 may be formed of, for example, a material containing ceramics. Examples of the material containing ceramics include aluminum nitride (AlN) and alumina (Al₂O₃). The substrate 20 formed of the material containing ceramics has high heat dissipation performance and is capable of suppressing a temperature of the semiconductor light emitting device 10 from becoming excessively high.

### Front Surface Electrode and Back Surface Electrode

As shown in FIGS. 1, 2, and 4, the semiconductor light emitting device 10 includes first to fourth front surface electrodes 51S to 54S provided over the substrate front surface 21. The first to fourth front surface electrodes 51S to 54S are formed of, for example, a material appropriately selected from one or more of Ti (titanium), TiN (titanium nitride), Au (gold), Ag (silver), Cu (copper), Al (aluminum), and W (tungsten).

As shown in FIG. 1, the first front surface electrode 51S is disposed closer to the first substrate side surface 23 than a center of the substrate front surface 21 in the X direction in a plan view. Further, the first front surface electrode 51S is disposed closer to the third substrate side surface 25 than a center of the substrate front surface 21 in the Y direction. In one example, the first front surface electrode 51S is formed in a rectangular shape with the length thereof in the Y direction being longer than the length thereof in the X direction in a plan view. The disposed position and shape of the first front surface electrode 51S on the substrate front surface 21 may be changed arbitrarily.

The second front surface electrode 52S is spaced apart from the first front surface electrode 51S. The second front surface electrode 52S is spaced apart from the first front surface electrode 51S in the Y direction in a plan view. The second front surface electrode 52S is disposed closer to the first substrate side surface 23 than the center of the substrate front surface 21 in the X direction in a plan view. Further, the second front surface electrode 52S is disposed closer to the fourth substrate side surface 26 than the center of the substrate front surface 21 in the Y direction. It may be said that the second front surface electrode 52S is disposed between the first front surface electrode 51S and the fourth substrate side surface 26. In one example, the second front surface electrode 52S is formed in a rectangular shape with the length thereof in the Y direction being shorter than the length thereof in the X direction in a plan view. The disposed position and shape of the second front surface electrode 52S on the substrate front surface 21 may be changed arbitrarily.

The third front surface electrode 53S is spaced apart from the first front surface electrode 51S. The third front surface electrode 53S is spaced apart from the first front surface electrode 51S in the X direction in a plan view. The third front surface electrode 53S is disposed closer to the second substrate side surface 24 than the center of the substrate front surface 21 in the X direction in a plan view. Further, the third front surface electrode 53S is disposed closer to the third substrate side surface 25 than the center of the substrate front surface 21 in the Y direction. In one example, the third front surface electrode 53S is formed in a rectangular shape with the length thereof in the Y direction being shorter than the length thereof in the X direction in a plan view. The disposed position and shape of the third front surface electrode 53S on the substrate front surface 21 may be changed arbitrarily.

The fourth front surface electrode 54S is spaced apart from the third front surface electrode 53S. The fourth front surface electrode 54S is spaced apart from the third front surface electrode 53S in the Y direction in a plan view. The fourth front surface electrode 54S is disposed closer to the second substrate side surface 24 than the center of the substrate front surface 21 in the X direction in a plan view. Further, the fourth front surface electrode 54S is disposed closer to the fourth substrate side surface 26 than the center of the substrate front surface 21 in the Y direction. It may be said that the fourth front surface electrode 54S is disposed between the third front surface electrode 53S and the fourth substrate side surface 26. In one example, the fourth front surface electrode 54S is formed in a rectangular shape with the length thereof in the Y direction being shorter than the length thereof in the X direction in a plan view. The disposed position and shape of the fourth front surface electrode 54S on the substrate front surface 21 may be changed arbitrarily.

As shown in FIGS. 2 to 4, the semiconductor light emitting device 10 includes first to fourth back surface electrodes 51R to 54R provided over the back surface 22 of the substrate. The first to fourth back surface electrodes 51R to 54R are formed of, for example, a material appropriately selected from one or more of Ti, TiN, Au, Ag, Cu, Al, and W.

As shown in FIG. 3, the first back surface electrode 51R is disposed closer to the first substrate side surface 23 than a center of the substrate back surface 22 in the X direction in a plan view. Further, the first back surface electrode 51R is disposed closer to the third substrate side surface 25 than a center of the substrate back surface 22 in the Y direction. In one example, the first back surface electrode 51R is formed in a rectangular shape with the length thereof in the Y direction being longer than the length thereof in the X direction in a plan view. In one example, the first back surface electrode 51R is formed to have the same size as the first front surface electrode 51S shown in FIG. 1. The disposed position and shape of the first back surface electrode 51R on the back surface 22 of the substrate may be changed arbitrarily.

The second back surface electrode 52R is spaced apart from the first back surface electrode 51R. The second back surface electrode 52R is spaced apart from the first back surface electrode 51R in the Y direction in a plan view. The second back surface electrode 52R is disposed closer to the first substrate side surface 23 than the center of the substrate back surface 22 in the X direction in a plan view. Further, the second back surface electrode 52R is disposed closer to the fourth substrate side surface 26 than the center of the substrate back surface 22 in the Y direction. In one example, the second back surface electrode 52R is formed in a rectangular shape with the length thereof in the Y direction being shorter than the length thereof in the X direction in a plan view. In one example, the second back surface electrode 52R is formed to have the same size as the second front surface electrode 52S shown in FIG. 1. The disposed position and shape of the second back surface electrode 52R on the back surface 22 of the substrate may be changed arbitrarily.

The third back surface electrode 53R is spaced apart from the first back surface electrode 51R. The third back surface electrode 53R is spaced apart from the first back surface electrode 51R in the X direction in a plan view. The third back surface electrode 53R is disposed closer to the second substrate side surface 24 than the center of the substrate back surface 22 in the X direction in a plan view. Further, the third back surface electrode 53R is disposed closer to the third substrate side surface 25 than the center of the substrate back surface 22 in the Y direction. In one example, the third back surface electrode 53R is formed in a rectangular shape with the length thereof in the Y direction being shorter than the length thereof in the X direction in a plan view. In one example, the third back surface electrode 53R is formed to have the same size as the third front surface electrode 53S shown in FIG. 1. The disposed position and shape of the third back surface electrode 53R on the back surface 22 of the substrate may be changed arbitrarily.

The fourth back surface electrode 54R is spaced apart from the third back surface electrode 53R. The fourth back surface electrode 54R is spaced apart from the third back surface electrode 53R in the Y direction in a plan view. The fourth back surface electrode 54R is disposed closer to the second substrate side surface 24 than the center of the substrate back surface 22 in the X direction in a plan view. Further, the fourth back surface electrode 54R is disposed closer to the fourth substrate side surface 26 than the center of the substrate back surface 22 in the Y direction. In one example, the fourth back surface electrode 54R is formed in a rectangular shape with the length thereof in the Y direction being shorter than the length thereof in the X direction in a plan view. In one example, the fourth back surface electrode 54R is formed to have the same size as the fourth front surface electrode 54S shown in FIG. 1. The disposed position and shape of the fourth back surface electrode 54R on the back surface 22 of the substrate may be changed arbitrarily.

As shown in FIGS. 1 to 3, the semiconductor light emitting device 10 includes first to fourth vias 51V to 54V provided in the substrate 20. In FIGS. 1 and 3, the first to fourth vias 51V to 54V are indicated by broken lines. The first to fourth vias 51V to 54V may be formed of, for example, a material appropriately selected from one or more of Ti, TiN, Au, Ag, Cu, Al, and W.

The first to fourth vias 51V to 54V penetrate the substrate 20 in the Z direction. The first via 51V electrically connects the first front surface electrode 51S and the first back surface electrode 51R. The second via 52V electrically connects the second front surface electrode 52S and the second back surface electrode 52R. The third via 53V electrically connects the third front surface electrode 53S and the third back surface electrode 53R. The fourth via 54V electrically connects the fourth front surface electrode 54S and the fourth back surface electrode 54R. The number of first to fourth vias 51V to 54V may be changed as appropriate.

### Light Emitting Sub-Mount

As shown in FIGS. 1 and 2, the light emitting sub-mount 60 is formed into a rectangular flat plate shape with the thickness direction thereof being the Z direction. The light emitting sub-mount 60 is formed of, for example, a conductive material. As the conductive material, for example, Cu, Al, or the like is used. In one example, the light emitting sub-mount 60 is formed of Cu.

The light emitting sub-mount 60 includes a sub-mount front surface 61 and a sub-mount back surface 62 facing opposite sides to each other. The sub-mount front surface 61 faces the same side as the substrate front surface 21 of the substrate 20, and the sub-mount back surface 62 faces the same side as the substrate back surface 22 of the substrate 20.

The light emitting sub-mount 60 is electrically connected to the third front surface electrode 53S by a conductive bonding material 91. The conductive bonding material 91 is in contact with the sub-mount back surface 62. In a plan view, a dimension of the light emitting sub-mount 60 in the X direction is smaller than a dimension of the third front surface electrode 53S in the X direction, and a dimension of the light emitting sub-mount 60 in the Y direction is smaller than a dimension of the third front surface electrode 53S in the Y direction. The conductive bonding material 91 may be, for example, solder paste, silver paste, gold paste, copper paste, or the like.

### Edge Light Emitting Element

The edge light emitting element 30 is spaced apart from the light receiving element 40 in the X direction. In one example, the edge light emitting element 30 is disposed at a position overlapping with the light receiving element 40 when viewed from the X direction. The edge light emitting element 30 is disposed closer to the second substrate side surface 24 than the light receiving element 40.

The edge light emitting element 30 is a laser diode that emits a laser beam of a predetermined wavelength band, and functions as a light source of the semiconductor light emitting device 10. As the edge light emitting element 30, for example, an edge light emitting type laser (EEL: Edge Emitting Laser) is used. The wavelength band of this laser beam may be a visible light band, or may be a long wavelength band having a longer wavelength than visible light such as ultraviolet rays or the like.

The edge light emitting element 30 is formed in a rectangular parallelepiped shape. In one example, the edge light emitting element 30 is formed in a rectangular shape with the length thereof in the Y direction being shorter than the length thereof in the X direction in a plan view. The shape of the edge light emitting element 30 in a plan view may be changed arbitrarily. In one example, the edge light emitting element 30 may have a square shape in a plan view. As used in this specification, the term “rectangular parallelepiped shape” includes a shape with chamfered corners and ridges, a shape with rounded corners and ridges, and a shape with a recess formed in a portion or the entirety of the corners and ridges. In addition, irregularities may be formed on a portion or the entirety of each surface. Furthermore, in the case of a “rectangular parallelepiped shape,” surfaces facing opposite sides to each other do not necessarily have to be completely parallel, and may be slightly inclined.

As shown in FIGS. 1 and 2, the edge light emitting element 30 includes a light emitting element front surface 31 and a light emitting element back surface 32 facing opposite sides to each other in the Z direction, a first element end surface 33 and a second element end surface 34 facing opposite sides to each other in the X direction, and element side surfaces 35 and 36 facing opposite sides to each other in the Y direction. The first element end surface 33 and the second element end surface 34, which constitute both end surfaces in the X direction, are configured by flat surfaces orthogonal to the light emitting element front surface 31 (light emitting element back surface 32). The first element end surface 33 and the second element end surface 34 face opposite sides. The semiconductor light emitting device 10 is configured to emit a first laser beam L1 from the first element end surface 33 in the X direction, which is an example of a first direction (X direction) intersecting the Z direction in a plan view. Further, the semiconductor light emitting device 10 is configured to emit a second laser beam L2 from the second element end surface 34 in a direction opposite to the emission direction of the first laser beam L1.

The edge light emitting element 30 includes a first light emitting electrode 37 formed over the light emitting element front surface 31, and a second light emitting electrode 38 formed over the light emitting element back surface 32. As shown in FIG. 1, the first light emitting electrode 37 is formed approximately at a center of the light emitting element front surface 31 in the Y direction in a plan view. A shape of the first light emitting electrode 37 in a plan view is a rectangle in which a length in the Y direction is shorter than a length in the X direction. As shown in FIG. 2, for example, the second light emitting electrode 38 is formed to have the same length as the light emitting element back surface 32 in the X direction. In one example, the first light emitting electrode 37 may form an anode, and the second light emitting electrode 38 may form a cathode. The first light emitting electrode 37 and the second light emitting electrode 38 may have a stacked structure of a plurality of conductive films.

The edge light emitting element 30 includes a semiconductor stacked structure composed of a plurality of semiconductor layers including a light emitting layer. The light emitting layer is composed of, for example, one or more active layers. The light emitting layer extends in the X direction. The edge light emitting element 30 is configured to emit a laser beam, which is generated from the light emitting layer by electric power supplied by the first light emitting electrode 37 and the second light emitting electrode 38, from the first element end surface 33 and the second element end surface 34. It may be said that the first element end surface 33 and the second element end surface 34 include emission regions 33A and 34A from which the laser beam is emitted. In FIG. 2, the emission regions 33A and 34A of the first element end surface 33 and the second element end surface 34 are clearly shown. In one example, the emission regions 33A and 34A are located closer to the light emitting element front surface 31 than a center of the thickness direction.

The edge light emitting element 30 is disposed over the light emitting sub-mount 60. The edge light emitting element 30 is bonded to the light emitting sub-mount 60 with the conductive bonding material 91. In one example, the edge light emitting element 30 is disposed with the second light emitting electrode 38 facing the sub-mount front surface 61 of the light emitting sub-mount 60. The second light emitting electrode 38 of the edge light emitting element 30 is electrically connected to the light emitting sub-mount 60 by the conductive bonding material 91. The conductive bonding material 91 is in contact with the sub-mount front surface 61.

As shown in FIG. 1, the edge light emitting element 30 is electrically connected to the fourth front surface electrode 54S. The first light emitting electrode 37 of the edge light emitting element 30 is electrically connected to the fourth front surface electrode 54S by a wire W1. The wire W1 corresponds to a “second wire.” In one example, the first light emitting electrode 37 may be electrically connected to the fourth front surface electrode 54S by a plurality of wires W1. In one example, a first end of the wire W1 is electrically connected to the first light emitting electrode 37, and a second end of the wire W1 is electrically connected to the fourth front surface electrode 54S. The first end of the wire W1 may be electrically connected to the fourth front surface electrode 54S, and the second end of the wire may be electrically connected to the first light emitting electrode 37. The wire W1 is, for example, a bonding wire formed by a wire bonding device, and is formed of a conductive material such as Au, Al, Cu, or the like.

### Light Receiving Sub-Mount

The semiconductor light emitting device 10 includes a light receiving sub-mount 70 disposed over the substrate front surface 21 of the substrate 20. In one example, the light receiving sub-mount 70 is disposed over the first front surface electrode 51S.

In one example, the light receiving sub-mount 70 is formed in a rectangular flat plate shape. The light receiving sub-mount 70 is formed in a rectangular shape when viewed from the Y direction. In one example, the light receiving sub-mount 70 is formed in a parallelogram shape when viewed from the Y direction.

The light receiving sub-mount 70 includes a mounting surface 71 and a mounting back surface 72 facing opposite sides to each other in the thickness direction of the light receiving sub-mount 70, an attaching surface 73 and a top surface 74 facing opposite sides to each other in the Z direction, and side surfaces 75 and 76 facing opposite sides to each other in the Y direction. In one example, the mounting surface 71, the mounting back surface 72, the attaching surface 73, and the top surface 74 are formed in a rectangular shape, and the side surfaces 75 and 76 are formed in a parallelogram shape. The light receiving sub-mount 70 is disposed with the attaching surface 73 facing the substrate front surface 21 of the substrate 20.

As shown in FIG. 1, the light receiving sub-mount 70 is disposed so as to straddle the first front surface electrode 51S and the second front surface electrode 52S. The light receiving sub-mount 70 is disposed so that the mounting surface 71 faces the second element end surface 34 of the edge light emitting element 30. In one example, the light receiving sub-mount 70 is bonded to the first front surface electrode 51S and the second front surface electrode 52S by using an adhesive 92. In one example, the adhesive 92 may include an insulating resin material such as an epoxy resin or the like.

As shown in FIGS. 1, 2, and 4, a first mounting electrode 77 and a second mounting electrode 78 are formed over the mounting surface 71. In one example, the first mounting electrode 77 and the second mounting electrode 78 are formed in a rectangular shape when viewed from a direction perpendicular to the mounting surface 71. In one example, the first mounting electrode 77 and the second mounting electrode 78 are formed over the mounting surface 71 so as to extend from an end near the attaching surface 73 toward an end near the top surface 74. The first mounting electrode 77 and the second mounting electrode 78 may be formed of, for example, a material containing one or more substances appropriately selected from Ti, TiN, Au, Ag, Cu, Al, and W.

The first mounting electrode 77 is electrically connected to the first front surface electrode 51S by a conductive bonding material 93. The second mounting electrode 78 is electrically connected to the second front surface electrode 52S by the conductive bonding material 93. The conductive bonding material 93 may be, for example, a Pb (lead)-free solder such as a Sn (tin)-Ag-Cu-based solder.

The mounting surface 71 of the light receiving sub-mount 70 may extend along a direction intersecting the substrate front surface 21 when viewed from the Y direction. An angle Al of the mounting surface 71 with respect to the substrate front surface 21 may be determined by an angle between the mounting surface 71 of the light receiving sub-mount 70 and the attaching surface 73 facing the substrate front surface 21. The angle Al between the mounting surface 71 and the attaching surface 73 may be called the inclination angle Al of the mounting surface 71. The inclination angle Al may be 60 degrees or more and 90 degrees or less.

The light receiving sub-mount 70 of the first embodiment is formed such that the mounting surface 71 extends away from the second element end surface 34 as it extends away from the substrate front surface 21 in the X direction. The inclination angle Al of the light receiving sub-mount 70 of the first embodiment may be 60 degrees or more and less than 90 degrees.

### Light Receiving Element

As shown in FIGS. 1, 2, and 4, the light receiving element 40 is mounted over the light receiving sub-mount 70. The light receiving element 40 is mounted on the mounting surface 71 of the light receiving sub-mount 70.

As shown in FIGS. 1 and 2, the light receiving element 40 is formed in a rectangular flat plate shape. The light receiving element 40 includes a light receiving element front surface 41 and a light receiving element back surface 42 facing opposite sides to each other in the thickness direction thereof.

The light receiving element 40 is, for example, a photo diode (PD). The light receiving element 40 includes a light receiving portion 43. The light receiving portion 43 is formed at the light receiving element front surface 41. A formation range of the light receiving portion 43 is defined, for example, by a p-type well region formed in an n-type semiconductor substrate provided at the light receiving element 40. The light receiving element 40 further includes a first light receiving electrode 44 and a second light receiving electrode 45. As shown in FIGS. 1 and 2, the first light receiving electrode 44 is formed over the light receiving element front surface 41. Further, the second light receiving electrode 45 is formed over the light receiving element back surface 42. The first light receiving electrode 44 constitutes one of an anode and a cathode of the photodiode, and the second light receiving electrode 45 constitutes the other of the anode and the cathode of the photodiode. In the first embodiment, the first light receiving electrode 44 constitutes the anode, and the second light receiving electrode 45 constitutes the cathode. The light receiving element 40 is configured such that a current flows from the first light receiving electrode 44 to the second light receiving electrode 45 of the light receiving element 40 depending on an amount of light irradiated onto the light receiving portion 43.

The light receiving element 40 is bonded to a first mounting electrode 77 provided over the mounting surface 71 of the light receiving sub-mount 70. The light receiving element 40 is disposed with the second light receiving electrode 45 facing the first mounting electrode 77. The second light receiving electrode 45 is electrically connected to the first mounting electrode 77 by the conductive bonding material 91.

The first light receiving electrode 44 of the light receiving element 40 is electrically connected to the second mounting electrode 78 by a wire W2. The wire W2 corresponds to a “first wire.” In one example, a first end of the wire W2 is electrically connected to the first light receiving electrode 44, and a second end of the wire W2 is electrically connected to the second mounting electrode 78. The second end of the wire W2 may be electrically connected to the first light receiving electrode 44, and the first end of the wire W2 may be electrically connected to the second mounting electrode 78. The wire W2 is, for example, a bonding wire formed by a wire bonding device, and is formed of a conductive material such as Au, Al, Cu, or the like.

The light receiving portion 43 of the light receiving element 40 mounted on the light receiving sub-mount 70 faces in the same direction as the mounting surface 71 of the light receiving sub-mount 70. The mounting surface 71 faces the second element end surface 34 of the edge light emitting element 30. Therefore, the light receiving portion 43 of the light receiving element 40 faces the second element end surface 34 of the edge light emitting element 30. The mounting surface 71 of the light receiving sub-mount 70 is formed so as to extend away from the second element end surface 34 as it extends away from the substrate front surface 21 in the Z direction. Therefore, it may be said that the light receiving element 40 is disposed such that the light receiving element front surface 41 extends away from the second element end surface 34 as it extends away from the substrate front surface 21 in the Z direction.

The light receiving sub-mount 70 is disposed such that the light receiving element front surface 41 of the light receiving element 40 mounted on the light receiving sub-mount 70 is spaced apart from the second element end surface 34 of the edge light emitting element 30 in the X direction. A distance D1 between the second element end surface 34 of the edge light emitting element 30 and the light receiving element front surface 41 of the light receiving element 40 is preferably 0.5 mm or more and 2.6 mm or less. The distance D1 may be a distance in the X direction between a position on the light receiving element front surface 41 of the light receiving element 40, which is located at the same position as the emission region 34A of the second element end surface 34 in the Z direction, and the second element end surface 34 of the edge light emitting element 30.

### Cover Member

As shown in FIGS. 1, 2, and 4, the semiconductor light emitting device 10 includes a cover member 80. The cover member 80 accommodates at least a portion of the edge light emitting element 30 and at least a portion of the light receiving element 40. The cover member 80 shown in FIG. 2 accommodates the entire edge light emitting element 30 and the entire light receiving element 40.

The cover member 80 is provided over the substrate 20. The cover member is attached to the substrate front surface 21 of the substrate 20, for example, by an adhesive. The semiconductor light emitting device 10 includes a sealed space 88 formed between an inner surface of the cover member and the substrate front surface 21 of the substrate 20. It may be said that the edge light emitting element 30 and the light receiving element 40 are disposed within the sealed space 88.

The cover member 80 is formed in a box shape that opens toward the substrate 20. The cover member 80 includes a main body 81. The main body 81 includes an opening 82 through which a laser beam emitted from the first element end surface 33 of the edge light emitting element 30 passes. The main body 81 includes side walls 83 and 84 extending along the third and fourth substrate side surfaces 25 and 26 of the substrate 20, a side wall 85 extending along the first substrate side surface 23 of the substrate 20, and an upper wall 86 that covers the edge light emitting element 30 and the light receiving element 40 in the Z direction. The side walls 83, 84, and 85 are formed in a flat plate shape so as to extend along the substrate side surfaces 25, 26, and 23. The upper wall 86 is formed in a flat plate shape orthogonal to the Z direction.

The cover member 80 may include a window member 87 that closes the opening 82 of the main body 81. The window member 87 is formed to extend along the substrate side surface 24 of the substrate 20. The window member 87 is formed in a flat plate shape extending along the substrate side surface 24.

The main body 81 may be formed of a material that is transparent to the laser beam emitted from the edge light emitting element 30. The main body 81 may be formed of a glass material, or a resin material such as a silicon resin, an epoxy resin, an acrylic resin, or the like. The main body 81 may be formed of a material that blocks the laser beam emitted from the edge light emitting element 30. The main body 81 may be formed of a metal material, or a material containing ceramics.

The window member 87 may be formed of a material that is transparent to the laser beam emitted from the edge light emitting element 30. The main body 81 may be formed of a glass material, or a resin material such as a silicon resin, an epoxy resin, an acrylic resin, or the like. The window member 87 may be omitted. By omitting the window member 87, a lens or the like for condensing the first laser beam L1 emitted from the first element end surface 33 may be disposed close to the first element end surface 33.

### Operation

The operation of the semiconductor light emitting device 10 of the first embodiment is described. A light output of the edge light emitting element 30 is changed depending on the temperature and the like. In one example, the light output of the edge light emitting element 30 decreases as a temperature of the edge light emitting element 30 increases. A system using the laser beam is required to have a constant light output.

An output of the first laser beam L1 emitted from the first element end surface 33 of the edge light emitting element 30 and an output of the second laser beam L2 emitted from the second element end surface 34 have a correlation. A ratio of the light output of the first laser beam L1 and the light output of the second laser beam L2 may be set to 9:1, for example. Therefore, in the semiconductor light emitting device 10, the second laser beam L2 emitted from the second element end surface 34 of the edge light emitting element 30 is received by the light receiving element 40, and a so-called APC (Auto Power Control) drive is performed in which a drive current of the edge light emitting element 30 is controlled so as to keep an output current of the light receiving element 40 constant, that is, keep the laser beam L2 constant. Thus, it is possible to obtain the first laser beam L1 with a constant output. It is also possible to grasp the output of the first laser beam L1 from an output signal of the light receiving element 40 and then control the drive current of the edge light emitting element 30 so that the output of the first laser beam L1 has a predetermined value.

The light receiving element 40 is mounted on the light receiving sub-mount 70 that includes the mounting surface 71 facing the second element end surface 34 of the edge light emitting element 30. Therefore, the light receiving element front surface 41 including the light receiving portion 43 of the light receiving element 40 faces the second element end surface 34 of the edge light emitting element 30. As a result, it is possible for the light receiving element 40 to directly receive the second laser beam L2 from the second element end surface 34 of the edge light emitting element 30. Therefore, in the semiconductor light emitting device 10 in which the edge light emitting element 30 and the light receiving element 40 are provided over the substrate front surface 21 of the substrate 20, the second laser beam L2 from the edge light emitting element 30 can be easily received by the light receiving portion 43 of the light receiving element 40.

The first laser beam L1 and the second laser beam L2 emitted from the edge light emitting element 30 spread from the emission regions 33A and 34A. A light intensity of the first laser beam L1 decreases toward a periphery from an auxiliary straight line (an optical axis of the first laser beam L1) that passes through the emission region 33A perpendicularly to the first element end surface 33. In one example, at a position having an angle of 30 degrees with respect to the optical axis, the amount of light becomes 1/10 or less. A light intensity of the second laser beam L2 has the same distribution as the light intensity of the first laser beam. On the other hand, the distance D1 from the second element end surface 34 of the edge light emitting element 30 to the light receiving element front surface 41 of the light receiving element 40 is preferably 0.5 mm or more and 2.6 mm or less. By setting such a distance D1, the second laser beam L2 of the edge light emitting element 30 may be efficiently received without increasing a size of the light receiving element 40.

When the light receiving element 40 is made larger, a height of the cover member 80 that accommodates the edge light emitting element 30 and the light receiving element 40 increases. In other words, the size of the light receiving element 40 affects a size of the semiconductor light emitting device 10 in the Z direction. Therefore, by disposing the light receiving element 40 at the distance D1 as described above, it is possible to suppress the semiconductor light emitting device 10 from increasing in size.

The mounting surface 71 of the light receiving sub-mount 70 is formed so as to extend away from the second element end surface 34 as it extends away from the substrate front surface 21 in the Z direction. The angle A1 of the mounting surface 71 with respect to the substrate front surface 21 may also be determined by the angle A1 between the mounting surface 71 of the light receiving sub-mount 70 and the attaching surface 73 facing the substrate front surface 21. The angle A1 between the mounting surface 71 and the attaching surface 73 may be called the inclination angle A1 of the mounting surface 71. The inclination angle A1 may be 60 degrees or more and 90 degrees or less.

The semiconductor light emitting device 10 includes the first to fourth back surface electrodes 51R to 54R on the substrate back surface 22 of the substrate 20. The first back surface electrode 51R and the second back surface electrode 52R are electrically connected to the light receiving element 40. The third back surface electrode 53R and the fourth back surface electrode 54R are electrically connected to the edge light emitting element 30. Therefore, the semiconductor light emitting device 10 is mounted with the substrate back surface 22 facing a substrate front surface on which, for example, a driving circuit for the edge light emitting element 30 and the like are formed. In this way, the semiconductor light emitting device 10 is configured as a surface-mounted package structure.

The semiconductor light emitting device 10 includes the edge light emitting element 30 configured to emit the first laser beam L1 and the second laser beam L2, and the light receiving element 40 configured to receive the second laser beam L2 emitted from the second element end surface 34 of the edge light emitting element 30. In one example, the output signal (output current) of the light receiving element 40 may be used for so-called APC driving. Furthermore, the output signal (output current) of the light receiving element 40 may be used to check the operation of the edge light emitting element 30.

The semiconductor light emitting device 10 may use so-called APC driving, which controls a current supplied to the edge light emitting element 30 so that the light output of the first laser beam L1 and the second laser beam L2 of the edge light emitting element 30 is kept constant. More specifically, a controller provided outside the semiconductor light emitting device 10 and configured to control the current supplied to the edge light emitting element 30 receives a signal corresponding to the second laser beam L2 of the edge light emitting element 30 received by the light receiving element 40. In one example, the signal of the light receiving element 40 is outputted to the controller via the third back surface electrode 53R. The controller receives the signal from the light receiving element 40 by being electrically connected to the third back surface electrode 53R. Then, the controller controls the current supplied to the edge light emitting element 30 according to the difference between the received signal and an output setting value, which is a preset light output. In one example, the controller controls the current supplied to the edge light emitting element 30 so that the level of the received signal matches the output setting value.

### Effect

According to the semiconductor light emitting device 10 of the first embodiment, the following effects are obtained.
(1-1) The semiconductor light emitting device 10 includes: the substrate 20 including the substrate front surface 21; the edge light emitting element 30 mounted on the substrate front surface 21, the edge light emitting element 30 including the first element end surface 33 facing the X direction intersecting the Z direction with respect to the substrate front surface 21 and the second element end surface 34 facing an opposite direction to the first element end surface 33, the first element end surface 33 and the second element end surface 34 configured to emit light; the light receiving sub-mount 70 provided over the substrate front surface 21 and including the mounting surface 71 facing the second element end surface 34; and the light receiving element 40 mounted on the mounting surface 71 and including the light receiving portion 43 provided over the light receiving element front surface 41 to face the second element end surface 34.

The light receiving element 40 of the semiconductor light emitting device 10 is mounted on a light receiving sub-mount 70 including a mounting surface 71 facing the second element end surface 34 of the edge light emitting element 30. Therefore, the light receiving element front surface 41 including the light receiving portion 43 of the light receiving element 40 faces the second element end surface 34 of the edge light emitting element 30. Thus, the light receiving element 40 can directly receive the second laser beam L2 from the second element end surface 34 of the edge light emitting element 30. Accordingly, in the semiconductor light emitting device 10 in which the edge light emitting element 30 and the light receiving element 40 are provided over the substrate front surface 21 of the substrate 20, the second laser beam L2 from the edge light emitting element 30 can be easily received by the light receiving portion 43 of the light receiving element 40.
(1-2) The light receiving sub-mount 70 includes the first mounting electrode 77 and the second mounting electrode 78. The light receiving element 40 is electrically connected to the first mounting electrode 77. The first light receiving electrode 44 of the light receiving element 40 is electrically connected to the second mounting electrode 78 by the wire W2. By mounting the light receiving element 40 on the light receiving sub-mount 70 in this manner, the light receiving sub-mount 70 and the light receiving element 40 can be easily mounted on the substrate 20.
(1-3) The mounting surface 71 of the light receiving sub-mount 70 is formed so as to extend away from the second element end surface 34 as the mounting surface 71 extends away from the substrate front surface 21 in the Z direction. The angle A1 of the mounting surface 71 with respect to the substrate front surface 21 may be determined by the angle A1 between the mounting surface 71 of the light receiving sub-mount 70 and the attaching surface 73 facing the substrate front surface 21. The angle A1 between the mounting surface 71 and the attaching surface 73 may be called the inclination angle A1 of the mounting surface 71. The inclination angle A1 may be 60 degrees or more and 90 degrees or less. With this configuration, the light receiving element 40 can efficiently receive the second laser beam L2 from the edge light emitting element 30.
(1-4) The semiconductor light emitting device 10 includes the first front surface electrode 51S disposed over the substrate front surface 21 of the substrate 20, and the light receiving sub- mount 70 is disposed over the first front surface electrode 51S. With this configuration, the first mounting electrode 77 of the light receiving sub-mount 70 can be easily connected to the first front surface electrode 51S.
(1-5) The semiconductor light emitting device 10 includes the first front surface electrode 51S disposed over the substrate front surface 21 of the substrate 20, and the second front surface electrode 52S disposed to be spaced apart from the first front surface electrode 51S in the Y direction. The light receiving sub-mount 70 is disposed so as to straddle the first front surface electrode 51S and the second front surface electrode 52S. With this configuration, the first mounting electrode 77 and the second mounting electrode 78 of the light receiving sub-mount 70 can be easily connected to the first front surface electrode 51S and the second front surface electrode 52S.
(1-6) The semiconductor light emitting device 10 includes the first front surface electrode 51S formed over the substrate front surface 21 of the substrate 20, and the light receiving sub- mount 70 is disposed over the first front surface electrode 51S. With this configuration, the position of the light receiving sub-mount 70 can be easily changed. Therefore, the distance D1 between the light receiving element 40 mounted on the light receiving sub-mount 70 and the edge light emitting element 30 can be easily changed.
(1-7) The distance D1 from the second element end surface 34 of the edge light emitting element 30 to the light receiving element front surface 41 of the light receiving element 40 is preferably 0.5 mm or more and 2.6 mm or less. By setting such a distance D1, the second laser beam L2 of the edge light emitting element 30 can be efficiently received without increasing the size of the light receiving element 40.
(1-8) When the light receiving element 40 is made larger, the height of the cover member 80 that accommodates the edge light emitting element 30 and the light receiving element 40 increases. In other words, the size of the light receiving element 40 affects the size of the semiconductor light emitting device 10 in the Z direction. The distance D1 from the second element end surface 34 of the edge light emitting element 30 to the light receiving element front surface 41 of the light receiving element 40 is preferably 0.5 mm or more and 2.6 mm or less. By arranging the light receiving element 40 at such a distance D1, it is possible to suppress the semiconductor light emitting device 10 from increasing in size.
(1-9) The semiconductor light emitting device 10 includes the first to fourth back surface electrodes 51R to 54R on the substrate back surface 22 of the substrate 20. The first back surface electrode 51R and the second back surface electrode 52R are electrically connected to the light receiving element 40. The third back surface electrode 53R and the fourth back surface electrode 54R are electrically connected to the edge light emitting element 30. Therefore, the semiconductor light emitting device 10 is mounted with the substrate back surface 22 facing a front surface of a circuit board on which, for example, the driving circuit for the edge light emitting element 30 and the like are formed. In this way, the semiconductor light emitting device 10 is configured as a surface-mounted package structure. Therefore, the semiconductor light emitting device 10 can be easily mounted.
(1-10) The light receiving sub-mount 70 includes the mounting back surface 72 facing the opposite side to the mounting surface 71 on which the light receiving element 40 is mounted. By placing the mounting back surface 72 on a workbench, the light receiving element 40 can be easily mounted on the mounting surface 71.

### Second Embodiment

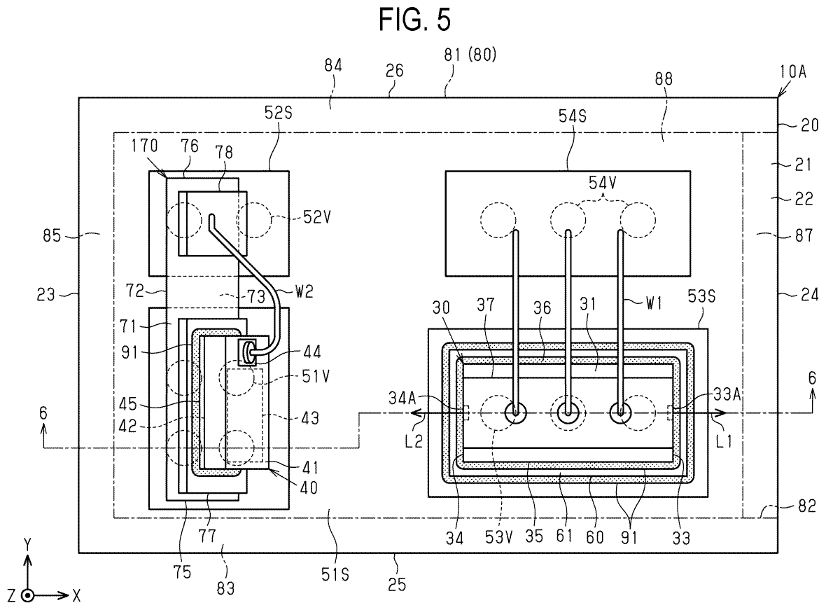

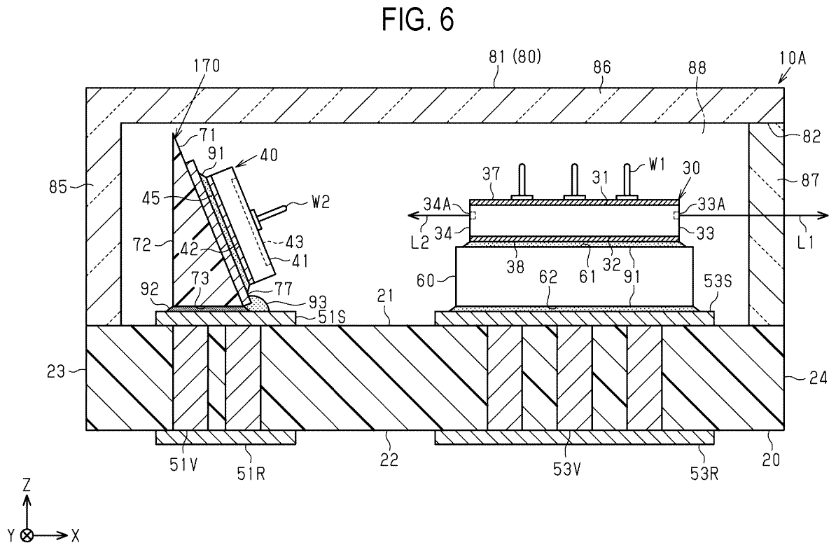

A semiconductor light emitting device 10A according to a second embodiment is described with reference to FIGS. 5 and 6. The semiconductor light emitting device 10A of the second embodiment differs from the semiconductor light emitting device 10 of the first embodiment in the shape of a light receiving sub-mount 170. The points differing from the semiconductor light emitting device 10 of the first embodiment are described below in detail. Further, the same components as those of the semiconductor light emitting device 10 of the first embodiment are designated by like reference numerals, and the detailed description thereof is omitted.

FIG. 5 is a schematic plan view of the semiconductor light emitting device 10A according to the second embodiment. FIG. 6 is a schematic cross-sectional view of the semiconductor light emitting device 10A taken along line 6-6 in FIG. 5. As shown in FIGS. 5 and 6, the semiconductor light emitting device 10A includes a light receiving sub-mount 170 disposed over the substrate front surface 21 of the substrate 20. In one example, the light receiving sub-mount 170 is placed over the first front surface electrode 51S. In one example, the light receiving sub-mount 170 is disposed so as to straddle the first front surface electrode 51S and the second front surface electrode 52S.

The light receiving sub-mount 170 is formed in a triangular shape when viewed from the Y direction. The light receiving sub-mount 170 includes an attaching surface 73 facing the substrate front surface 21, a mounting surface 71 facing the second element end surface 34 of the edge light emitting element 30, a mounting back surface 72 facing an opposite side to the mounting surface 71, and side surfaces 75 and 76 facing opposite sides to each other in the Y direction. In one example, the mounting surface 71, the mounting back surface 72, and the attaching surface 73 are formed in a rectangular shape, and the side surfaces 75 and 76 are formed in a triangular shape. In one example, the side surfaces 75 and 76 are formed in a right triangular shape with a side of the mounting surface 71 as a hypotenuse.

### Effect

According to the semiconductor light emitting device 10A of the second embodiment, the following effects are obtained.
(2-1) The same effects as the effects (1-1) to (1-9) of the semiconductor light emitting device 10 of the first embodiment are obtained.
(2-2) The light receiving sub-mount 170 is formed in a triangular shape when viewed from the Y direction. Therefore, the light receiving sub-mount 170 may be placed closer to the side wall 85 of the cover member 80.
(2-3) The side wall 85 of the cover member 80 may be brought close to the first front surface electrode 51S and the second front surface electrode 52S on which the light receiving sub-mount 170 is mounted. Therefore, it is possible to reduce a size of the semiconductor light emitting device 10A in the X direction.

### Third Embodiment

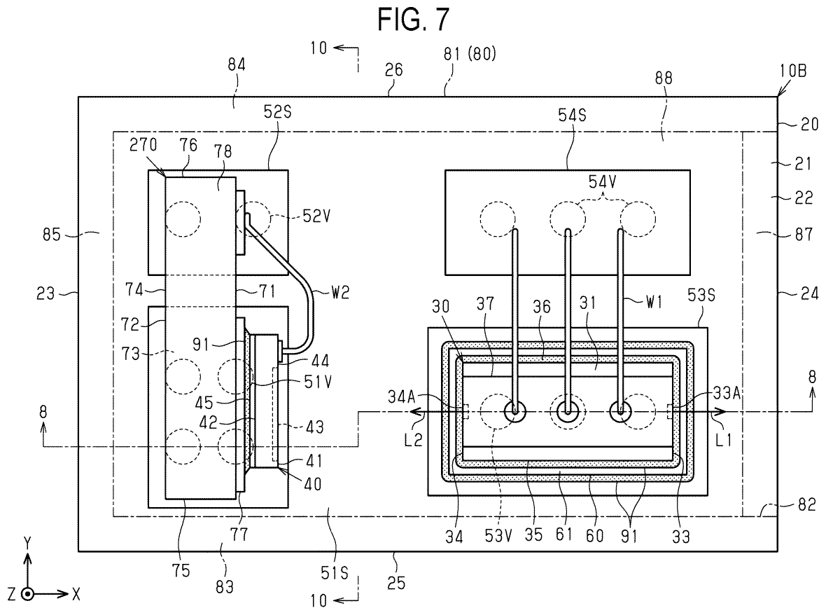

A semiconductor light emitting device 10B according to a third embodiment is described with reference to FIGS. 7 to 10. The semiconductor light emitting device 10B of the third embodiment differs from the semiconductor light emitting device 10 of the first embodiment in the shape of a light receiving sub-mount 270. The points differing from the semiconductor light emitting device 10 of the first embodiment are described below in detail. Further, the same components as those of the semiconductor light emitting device 10 of the first embodiment are designated by like reference numerals, and the detailed description thereof is omitted.

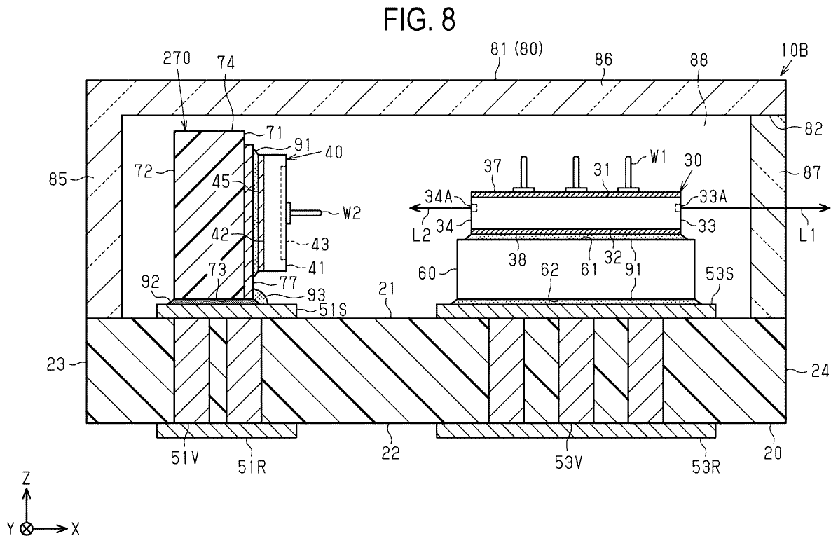

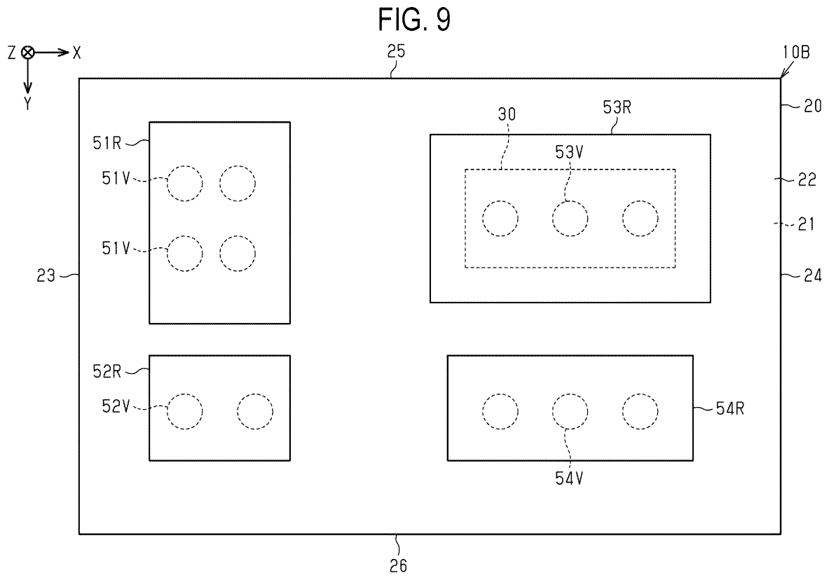

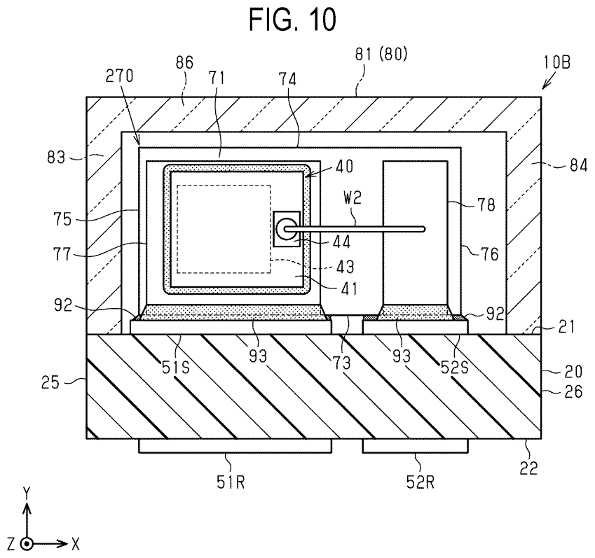

FIG. 7 is a schematic plan view of the semiconductor light emitting device 10B according to the third embodiment. FIG. 8 is a schematic cross-sectional view of the semiconductor light emitting device 10B taken along line 8-8 in FIG. 7. FIG. 9 is a schematic rear view of the semiconductor light emitting device 10B shown in FIG. 7. FIG. 10 is a schematic cross- sectional view of the semiconductor light emitting device 10B taken along line 10-10 in FIG. 7.

As shown in FIG. 7, the semiconductor light emitting device 10B includes the light receiving sub-mount 270 disposed over the substrate front surface 21 of the substrate 20. In one example, the light receiving sub-mount 270 is placed over the first front surface electrode 51S. In one example, the light receiving sub-mount 270 is disposed so as to straddle the first front surface electrode 51S and the second front surface electrode 52S.

In one example, the light receiving sub-mount 270 is formed into a rectangular flat plate shape. The light receiving sub-mount 270 is formed into a rectangular shape when viewed from the Y direction. In one example, the light receiving sub-mount 270 is formed in a rectangular shape when viewed from the Y direction.

The light receiving sub-mount 270 includes a mounting surface 71 and a mounting back surface 72 facing opposite sides to each other in a thickness direction of the light receiving sub- mount 270, an attaching surface 73 and a top surface 74 facing opposite sides to each other in the Z direction, and side surfaces 75 and 76 facing opposite sides to each other in the Y direction. In one example, the mounting surface 71, the mounting back surface 72, the attaching surface 73, the top surface 74, and the side surfaces 75 and 76 are formed in a rectangular shape. The light receiving sub-mount 270 is formed into a rectangular parallelepiped shape. The light receiving sub-mount 270 is disposed with the attaching surface 73 facing the substrate front surface 21 of the substrate 20.

The light receiving sub-mount 270 of the third embodiment is formed so that the mounting surface 71 is orthogonal to the substrate front surface 21. That is, in the light receiving sub-mount 270, the angle between the attaching surface 73 and the mounting surface 71 is 90 degrees.

According to the semiconductor light emitting device 10B of the third embodiment, the following effects are obtained.

(3-1) The same effects as those of the semiconductor light emitting device 10 of the first embodiment are obtained.

(3-2) The light receiving sub-mount 270 is formed in a rectangular shape when viewed from the Y direction. Therefore, the light receiving sub-mount 270 can be placed close to the side wall 85 of the cover member 80.

(3-3) The side wall 85 of the cover member 80 may be brought close to the first front surface electrode 51S and the second front surface electrode 52S on which the light receiving sub-mount 270 is mounted. Therefore, it is possible to reduce a size of the semiconductor light emitting device 10B in the X direction.

### Fourth Embodiment

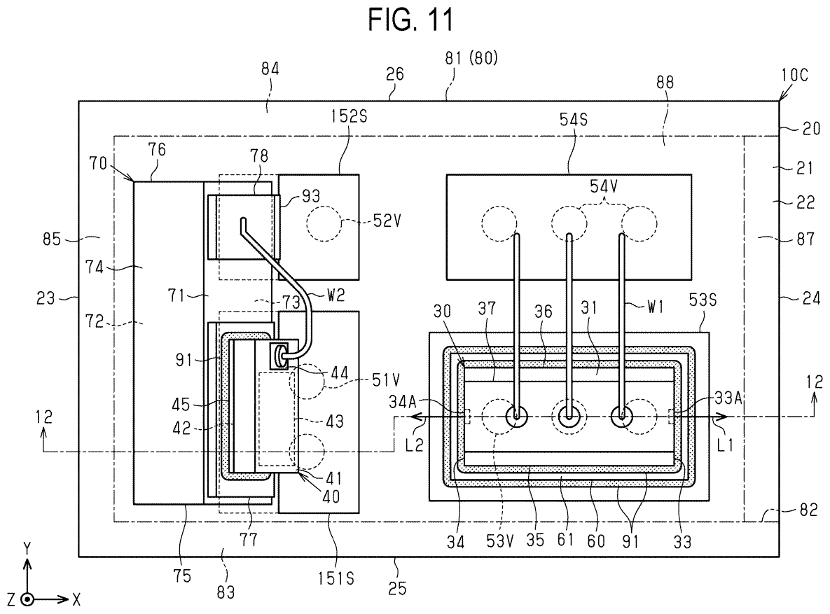

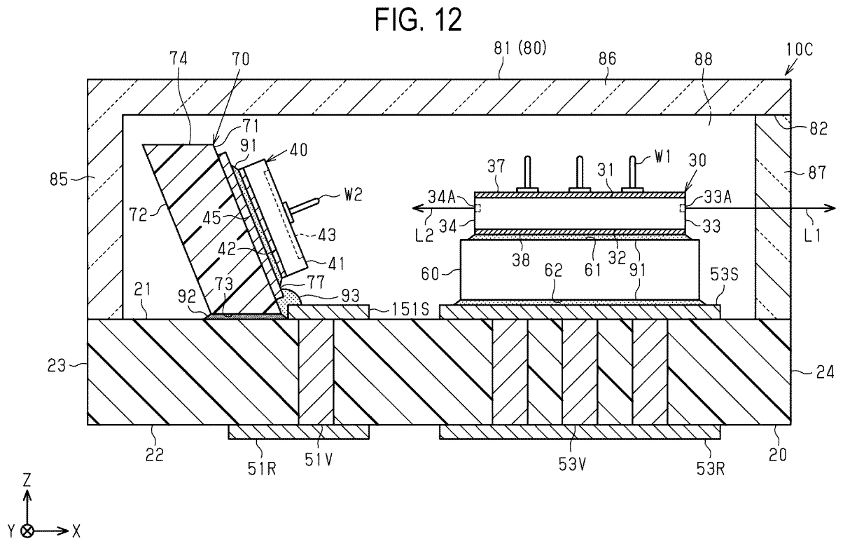

A semiconductor light emitting device 10C according to a fourth embodiment is described with reference to FIGS. 11 and 12. The semiconductor light emitting device 10C of the fourth embodiment differs from the semiconductor light emitting device 10 of the first embodiment in the shapes of first and second front surface electrodes 151S and 152S and the disposed position of the light receiving sub-mount 70. The points differing from the semiconductor light emitting device 10 of the first embodiment are described below in detail. Further, the same components as those of the semiconductor light emitting device 10 of the first embodiment are designated by like reference numerals, and the detailed description thereof is omitted.

FIG. 11 is a schematic plan view of the semiconductor light emitting device 10C according to the fourth embodiment. FIG. 12 is a schematic cross-sectional view of the semiconductor light emitting device 10C taken along line 12-12 in FIG. 11. As shown in FIGS. 11 and 12, the semiconductor light emitting device 10C includes a light receiving sub-mount 70 disposed over the substrate front surface 21 of the substrate 20. The light receiving sub-mount 70 of the fourth embodiment is disposed over the first front surface electrode 151S. The light receiving sub-mount 70 is disposed with the attaching surface 73 facing the substrate front surface 21 of the substrate 20. The light receiving sub-mount 70 is directly bonded to the substrate front surface 21 of the substrate 20 with the adhesive 92. It may be said that the light receiving sub-mount 70 is disposed at a position that does not overlap with the first front surface electrode 151S. That is, in the semiconductor light emitting device 10C of the fourth embodiment, the first front surface electrode 151S is not interposed between the substrate 20 and the light receiving sub-mount 70.

The first front surface electrode 151S is disposed between the light receiving sub-mount 70 and the third front surface electrode 53S. The first front surface electrode 151S is formed in a rectangular shape in which the length thereof in the Y direction is longer than the length thereof in the X direction. The first front surface electrode 151S is disposed so as to overlap with a portion of the first back surface electrode 51R provided over the substrate back surface 22 of the substrate 20. The first back surface electrode 51R may be formed to have the same size as the first front surface electrode 151S in a plan view.

The second front surface electrode 152S is spaced apart from the first front surface electrode 151S in the Y direction. It may be said that the second front surface electrode 152S is disposed between the light receiving sub-mount 70 and the fourth front surface electrode 54S. The second front surface electrode 152S is formed in a rectangular shape in which the length thereof in the Y direction is longer than the length thereof in the X direction. The second front surface electrode 152S is disposed so as to overlap with a portion of the second back surface electrode 52R provided over the substrate back surface 22 of the substrate 20. The second back surface electrode 52R may be formed to have the same size as the second front surface electrode 152S in a plan view.

The first mounting electrode 77 provided over the mounting surface 71 of the light receiving sub-mount 70 is electrically connected to the first front surface electrode 151S by the conductive bonding material 93. The second mounting electrode 78 provided over the mounting surface 71 of the light receiving sub-mount 70 is electrically connected to the second front surface electrode 152S by the conductive bonding material 93.

### Effect

According to the semiconductor light emitting device 10C of the fourth embodiment, the following effects are obtained.
(4-1) The same effects as (1-1) to (1-3) and (1-7) to (1-10) in the semiconductor light emitting device 10 of the first embodiment are obtained.

### Fifth Embodiment

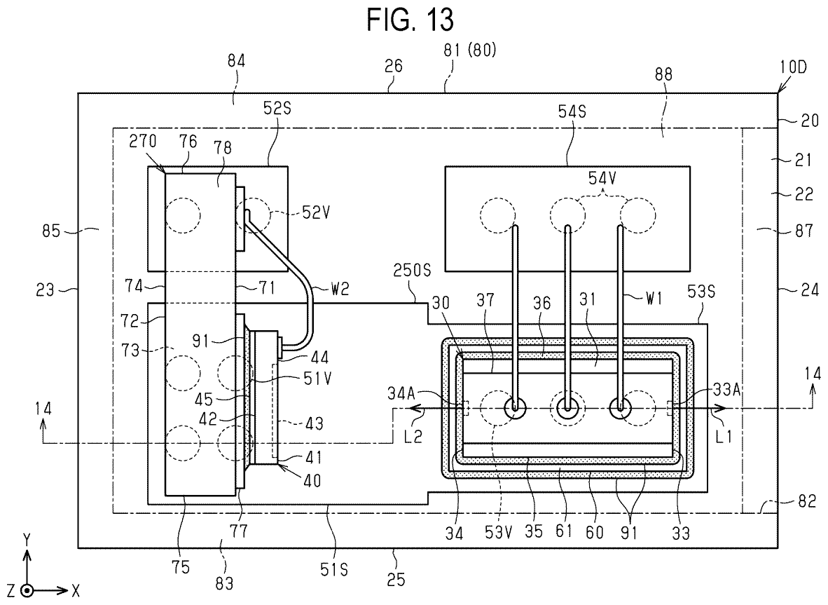

A semiconductor light emitting device 10D according to a fifth embodiment is described with reference to FIGS. 13 to 15. The semiconductor light emitting device 10D of the fifth embodiment differs from the semiconductor light emitting device 10B of the third embodiment in that it includes a front surface common electrode 250S and a back surface common electrode 250R. The points differing from the semiconductor light emitting device 10B of the third embodiment are described below in detail. Further, the same components as those of the semiconductor light emitting device 10B of the third embodiment are designated by like reference numerals, and the detailed description thereof is omitted.

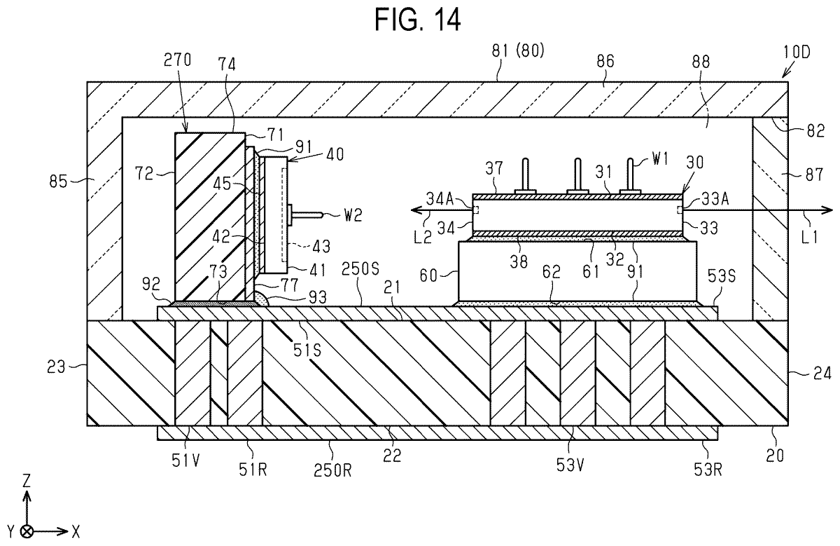

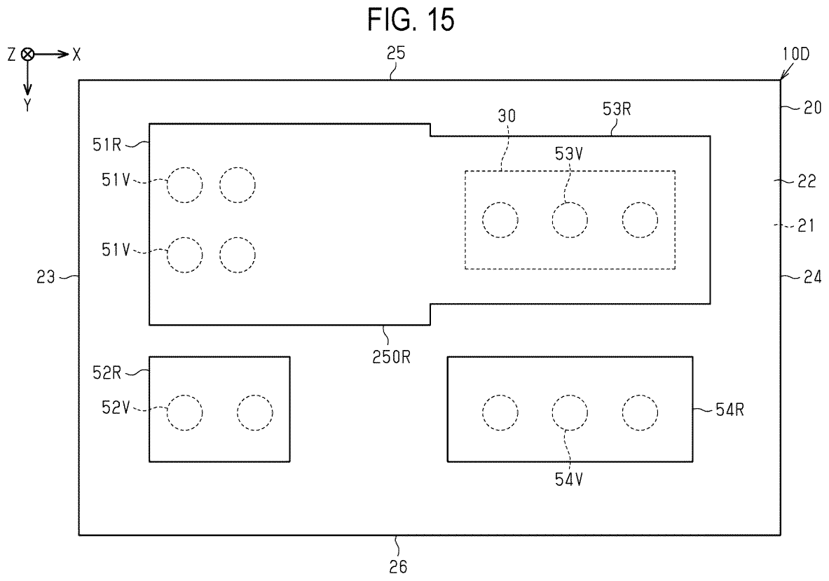

FIG. 13 is a schematic plan view of the semiconductor light emitting device 10D according to the fifth embodiment. FIG. 14 is a schematic cross-sectional view of the semiconductor light emitting device 10D taken along line 14-14 in FIG. 13. FIG. 15 is a schematic rear view of the semiconductor light emitting device 10D shown in FIG. 13.

As shown in FIGS. 13 and 15, the semiconductor light emitting device 10D includes the front surface common electrode 250S provided over the substrate front surface 21 of the substrate 20 and the back surface common electrode 250R provided over the substrate back surface 22 of the substrate 20. The front surface common electrode 250S is formed over the substrate front surface 21 so as to extend in the X direction. The front surface common electrode 250S is disposed close to the third substrate side surface 25. The front surface common electrode 250S includes the first front surface electrode 51S and the third front surface electrode 53S. The back surface common electrode 250R is formed over the substrate back surface 22 so as to extend in the X direction. The back surface common electrode 250R is disposed close to the third substrate side surface 25. The back surface common electrode 250R includes the first back surface electrode 51R and the third back surface electrode 53R.

Either the front surface common electrode 250S or the back surface common electrode 250R may be configured as a separated electrode. In one example, the semiconductor light emitting device 10D may include a front surface common electrode 250S, a first back surface electrode 51R, and a third back surface electrode 53R. Further, the semiconductor light emitting device 10D may include a first front surface electrode 51S, a third front surface electrode 53S, and a back surface common electrode 250R. The common electrodes may be the second front surface electrode 52S and the fourth front surface electrode 54S, and the second back surface electrode 52R and the fourth back surface electrode 54R.

### Effect

According to the semiconductor light emitting device 10D of the fifth embodiment, the following effects are obtained.
(5-1) The same effects as those of the semiconductor light emitting device 10B of the third embodiment are obtained.

### Sixth Embodiment

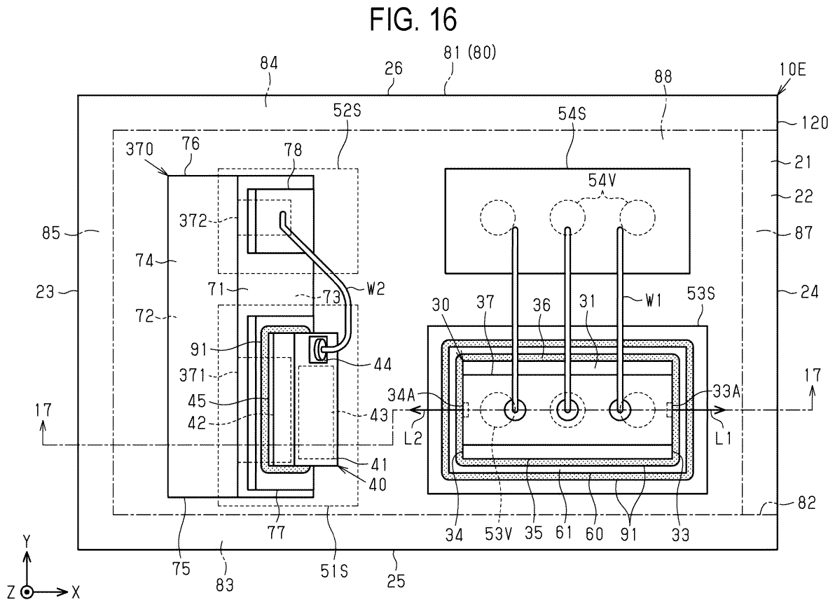

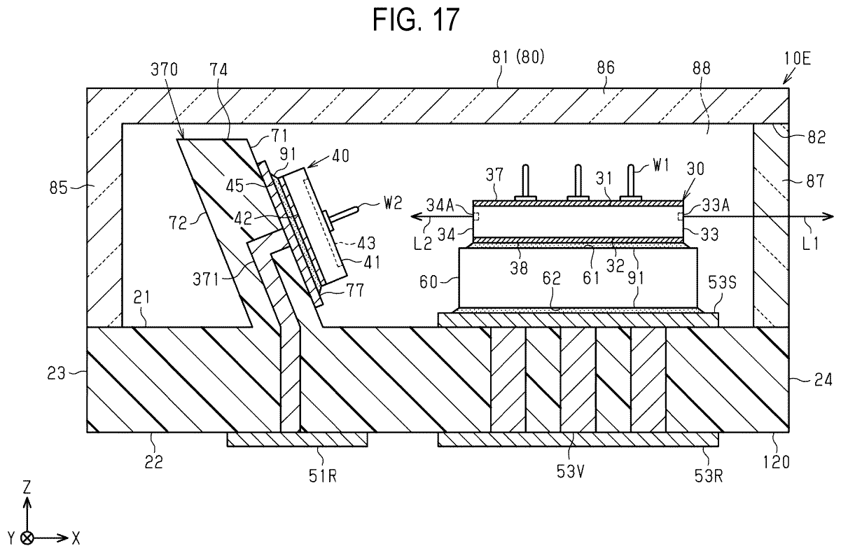

A semiconductor light emitting device 10E according to a sixth embodiment is described with reference to FIGS. 16 and 17. The semiconductor light emitting device 10E of the sixth embodiment differs from the semiconductor light emitting device 10 of the first embodiment in the shape of a substrate 120 and a light receiving sub-mount 370. The points differing from the semiconductor light emitting device 10 of the first embodiment are described below in detail. Further, the same components as those of the semiconductor light emitting device 10 of the first embodiment are designated by like reference numerals, and the detailed description thereof is omitted.

FIG. 16 is a schematic plan view of the semiconductor light emitting device 10E according to the sixth embodiment. FIG. 17 is a schematic cross-sectional view of the semiconductor light emitting device 10E taken along line 17-17 in FIG. 16. As shown in FIGS. 16 and 17, the semiconductor light emitting device 10E includes the light receiving sub-mount 370 provided on the substrate front surface 21 of the substrate 120. The light receiving sub- mount 370 of the sixth embodiment is formed integrally with the substrate 120. The light receiving sub-mount 370 and the substrate 120 are configured as an integral body connected to each other. It may be said that the substrate 120 of the sixth embodiment includes the light receiving sub-mount 370. In one example, the light receiving sub-mount 370 and the substrate 120 may be formed of a material containing ceramics or a resin material such as an epoxy resin or the like.

The semiconductor light emitting device 10E includes a first internal wiring 371 and a second internal wiring 372 provided inside the light receiving sub-mount 370 and the substrate 120. The first internal wiring 371 electrically connects the first mounting electrode 77 provided over the mounting surface 71 of the light receiving sub-mount 370 and the first back surface electrode 51R provided over the substrate back surface 22 of the substrate 120. The second internal wiring 372 electrically connects the second mounting electrode 78 provided over the mounting surface 71 of the light receiving sub-mount 370 and the second back surface electrode 52R provided over the substrate back surface 22 of the substrate 120.

### Effect

According to the semiconductor light emitting device 10E of the sixth embodiment, the following effects are obtained.
(6-1) The same effects as (1-1) to (1-3) and (1-7) to (1-10) in the semiconductor light emitting device 10 of the first embodiment are obtained.
(6-2) The light receiving sub-mount 370 and the substrate 120 are configured as an integral body connected to each other. Therefore, it is possible to suppress the peeling of the light receiving sub-mount 370. Further, it is possible to suppress the positional shift and the change in the angle of the mounting surface 71 against the edge light emitting element 30 disposed over the substrate front surface 21 of the substrate 120.
(6-3) The first mounting electrode 77 of the light receiving sub-mount 370 is electrically connected to the first back surface electrode 51R by the first internal wiring 371. The second mounting electrode 78 of the light receiving sub-mount 370 is electrically connected to the second back surface electrode 52R by the second internal wiring 372. Therefore, the adhesive 92 and the conductive bonding material 93 shown in FIG. 2 are not required. Furthermore, it is possible to suppress the occurrence of connection failures due to deterioration of the adhesive 92 or the conductive bonding material 93.

### Seventh Embodiment

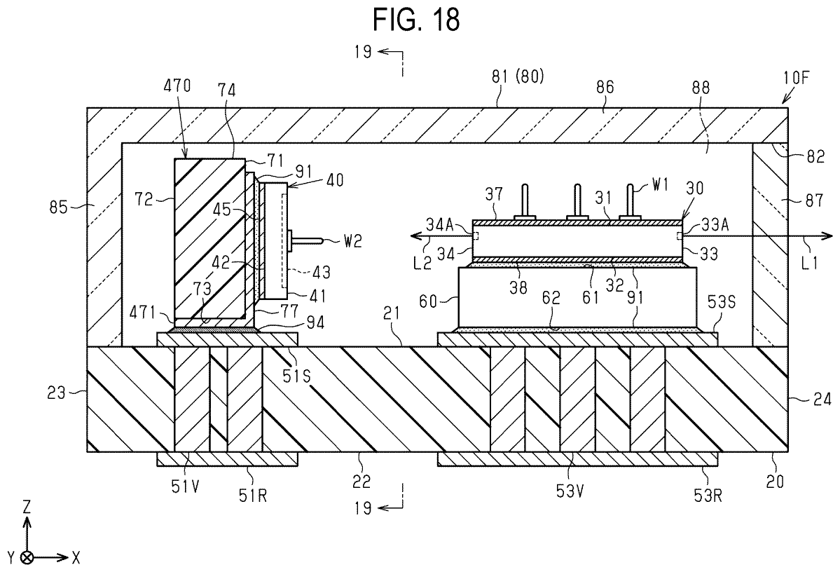

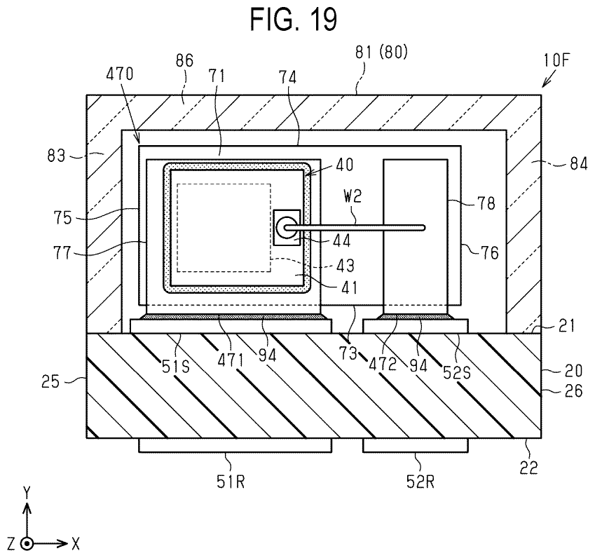

A semiconductor light emitting device 10F of a seventh embodiment is described with reference to FIGS. 18 and 19. The semiconductor light emitting device 10F of the seventh embodiment differs from the semiconductor light emitting device 10B of the third embodiment in the configuration of a light receiving sub-mount 470. The points different from the semiconductor light emitting device 10B of the third embodiment are described below in detail. Further, the same components as those of the semiconductor light emitting device 10B of the third embodiment are designated by like reference numerals, and the detailed description thereof is omitted.

FIG. 18 is a schematic cross-sectional view of the semiconductor light emitting device 10F according to the seventh embodiment. FIG. 19 is a schematic cross-sectional view of the semiconductor light emitting device 10F taken along line 19-19 in FIG. 18. As shown in FIGS. 18 and 19, the semiconductor light emitting device 10F includes the light receiving sub-mount 470 disposed on the substrate front surface 21 of the substrate 20. In one example, the light receiving sub-mount 470 is placed over the first front surface electrode 51S. In one example, the light receiving sub-mount 470 is disposed so as to straddle the first front surface electrode 51S and the second front surface electrode 52S.

The light receiving sub-mount 470 includes a first mounting electrode 471 and a second mounting electrode 472 provided over the attaching surface 73. The first mounting electrode 471 and the second mounting electrode 472 are spaced apart from each other in the Y direction. The first mounting electrode 471 is electrically connected to the first mounting electrode 77 of the mounting surface 71. The second mounting electrode 472 is electrically connected to the second mounting electrode 78 of the mounting surface 71.

The first mounting electrode 471 is electrically connected to the first front surface electrode 51S by a conductive bonding material 94. The second mounting electrode 472 is electrically connected to the second front surface electrode 52S by the conductive bonding material 94. The conductive bonding material 94 may be formed of the same material as the conductive bonding material 91, or may be formed of a different material.

### Effect

According to the semiconductor light emitting device 10F of the seventh embodiment, the following effects are obtained.
(7-1) The same effects as those of the semiconductor light emitting device 10B of the third embodiment are obtained.
(7-2) By mounting the light receiving sub-mount 470 on the first front surface electrode 51S and the second front surface electrode 52S, it is possible to electrically connect the first mounting electrode 77 and the second mounting electrode 78 to the first front surface electrode 51S and the second front surface electrode 52S. Therefore, the time and effort required to mount the light receiving sub-mount 470 may be reduced.

### Eighth Embodiment

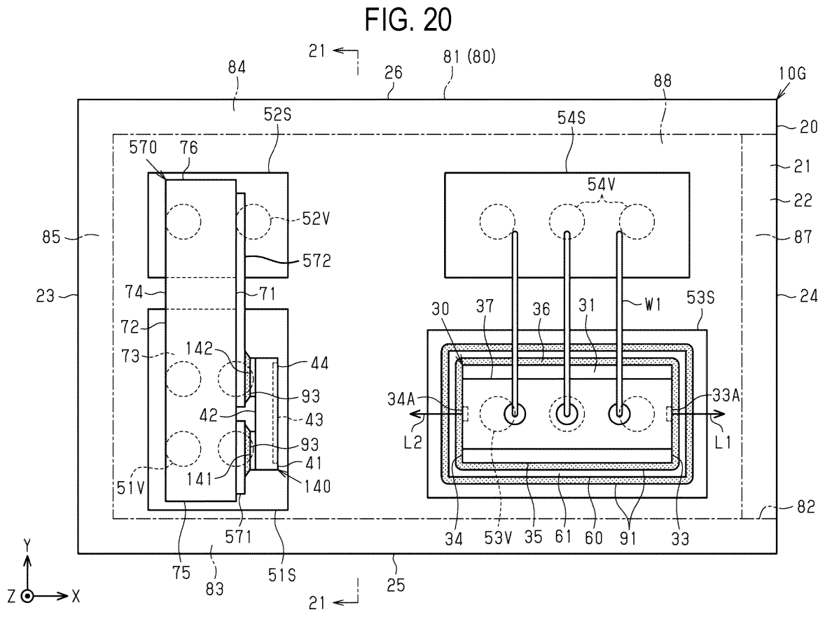

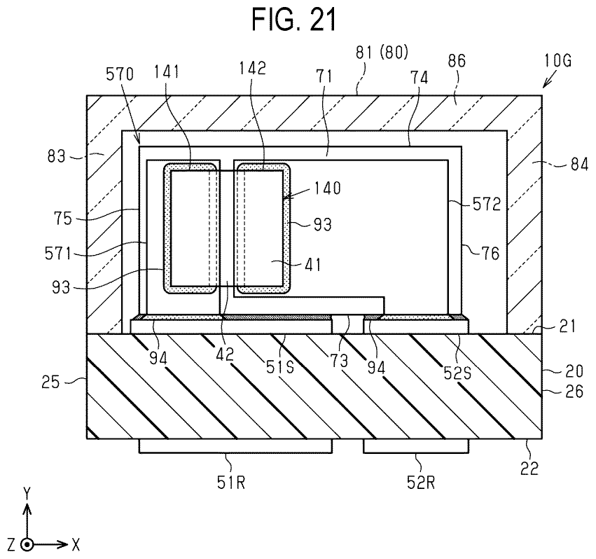

A semiconductor light emitting device 10G according to an eighth embodiment is described with reference to FIGS. 20 and 21. The semiconductor light emitting device 10G of the eighth embodiment differs from the semiconductor light emitting device 10B of the third embodiment in the shapes of a light receiving element 140 and a light receiving sub-mount 570. The points differing from the semiconductor light emitting device 10B of the third embodiment are described below in detail. Further, the same components as those of the semiconductor light emitting device 10B of the third embodiment are designated by like reference numerals, and the detailed description thereof is omitted.

FIG. 20 is a schematic cross-sectional view of the semiconductor light emitting device 10G according to the eighth embodiment. FIG. 21 is a schematic cross-sectional view of the semiconductor light emitting device 10G taken along line 21-21 in FIG. 20. As shown in FIGS. 20 and 21, the semiconductor light emitting device 10G includes the light receiving sub-mount 570 disposed over the substrate front surface 21 of the substrate 20, and the light receiving element 140 mounted on the light receiving sub-mount 570. In one example, the light receiving sub-mount 570 is placed over the first front surface electrode 51S. In one example, the light receiving sub-mount 570 is disposed so as to straddle the first front surface electrode 51S and the second front surface electrode 52S. The light receiving sub-mount 570 is bonded to the first front surface electrode 51S and the second front surface electrode 52S using the adhesive 92.

The light receiving element 140 is mounted on the mounting surface 71 of the light receiving sub-mount 570. The light receiving element 140 includes a first light receiving electrode 141 and a second light receiving electrode 142. The first light receiving electrode 141 and the second light receiving electrode 142 are provided over the light receiving element back surface 42. The light receiving element 140 is disposed with the first light receiving electrode 141 and the second light receiving electrode 142 facing the light receiving sub-mount 570. Further, the light receiving element 140 is disposed so that the first light receiving electrode 141 and the second light receiving electrode 142 are lined up in the Y direction.

The light receiving sub-mount 570 includes a first mounting electrode 571 and a second mounting electrode 572. As shown in FIG. 21, the first mounting electrode 571 is disposed over the mounting surface 71 near the side surface 75. The second mounting electrode 572 is disposed adjacent to the first mounting electrode 571 in the Y direction. As shown in FIG. 20, the second mounting electrode 572 is formed over the mounting surface 71 to extend to a position overlapping with the second front surface electrode 52S.

The first light receiving electrode 141 of the light receiving element 140 is electrically connected to the first mounting electrode 571 of the light receiving sub-mount 570 by the conductive bonding material 93. The second light receiving electrode 142 of the light receiving element 140 is electrically connected to the second mounting electrode 572 of the light receiving sub-mount 570 by the conductive bonding material 93.

### Effect

According to the semiconductor light emitting device 10G of the eighth embodiment, the following effects are obtained.
(8-1) The same effects as those of the semiconductor light emitting device 10B of the third embodiment are obtained.
(8-2) The light receiving element 140 includes the first light receiving electrode 141 and the second light receiving electrode 142 disposed on the light receiving element back surface 42. The first light receiving electrode 141 and the second light receiving electrode 142 are electrically connected to the first mounting electrode 571 and the second mounting electrode 572 of the light receiving sub-mount 570 by the conductive bonding material 93. It is possible to easily mount the light receiving element 140 on the light receiving sub-mount 570.

### Ninth Embodiment

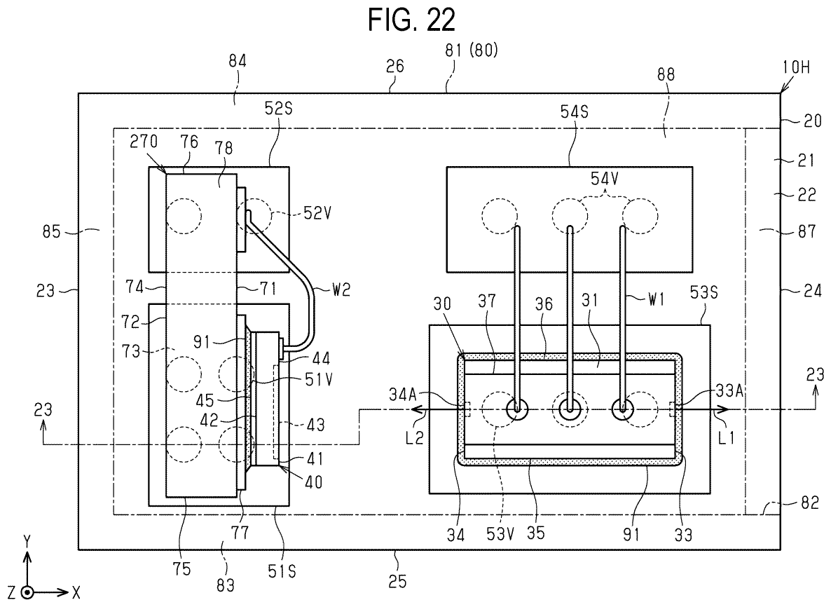

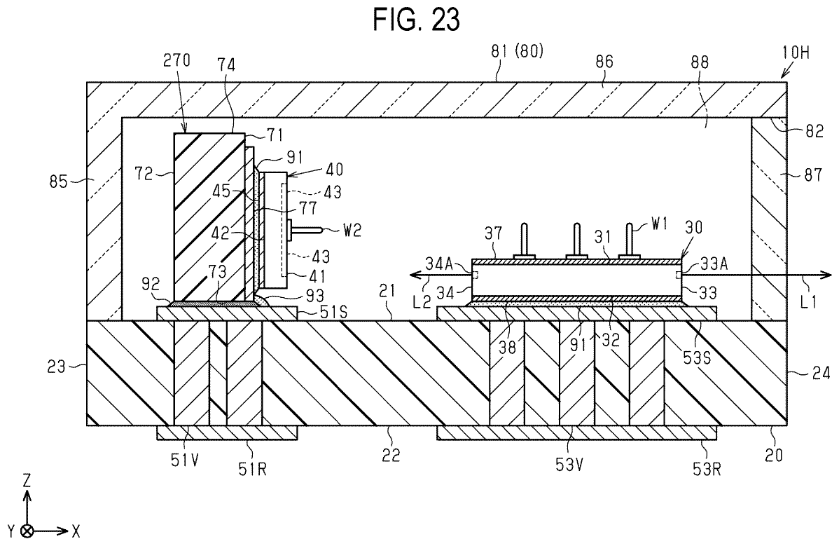

A semiconductor light emitting device 10H according to a ninth embodiment is described with reference to FIGS. 22 and 23. The semiconductor light emitting device 10H of the ninth embodiment differs from the semiconductor light emitting device 10B of the third embodiment in that the light emitting sub-mount 60 is not used. The points differing from the semiconductor light emitting device 10B of the third embodiment are described below in detail. Further, the same components as those of the semiconductor light emitting device 10B of the third embodiment are designated by like reference numerals, and the detailed description thereof is omitted.

FIG. 22 is a schematic cross-sectional view of the semiconductor light emitting device 10H according to the ninth embodiment. FIG. 23 is a schematic cross-sectional view of the semiconductor light emitting device 10H taken along line 23-23 in FIG. 22. As shown in FIGS. 22 and 23, the edge light emitting element 30 of the semiconductor light emitting device 10H is disposed over the third front surface electrode 53S. The second light emitting electrode 38 provided over the light emitting element back surface 32 of the edge light emitting element 30 faces the third front surface electrode 53S. The second light emitting electrode 38 is electrically connected to the third front surface electrode 53S by the conductive bonding material 91. The conductive bonding material 91 is in contact with the second light emitting electrode 38 and the third front surface electrode 53S.

As shown in FIG. 23, the light receiving element 40 may be disposed closer to the attaching surface 73 of the light receiving sub-mount 270 on the mounting surface 71. Thus, it is possible to increase an amount of reception of the second laser beam L2 emitted from the second element end surface 34 of the edge light emitting element 30.

### Effect

According to the semiconductor light emitting device 10H of the ninth embodiment, the following effects are obtained.
(9-1) The same effects as those of the semiconductor light emitting device 10B of the third embodiment are obtained.

### Modification

The above-described embodiment may be modified as follows, for example. The above-described embodiment and each modification to be described below may be combined with each other as long as no technical contradiction occurs. In the following modifications, the same parts as those of the above-described embodiment are designated by like reference numerals, and the detailed description thereof is omitted.

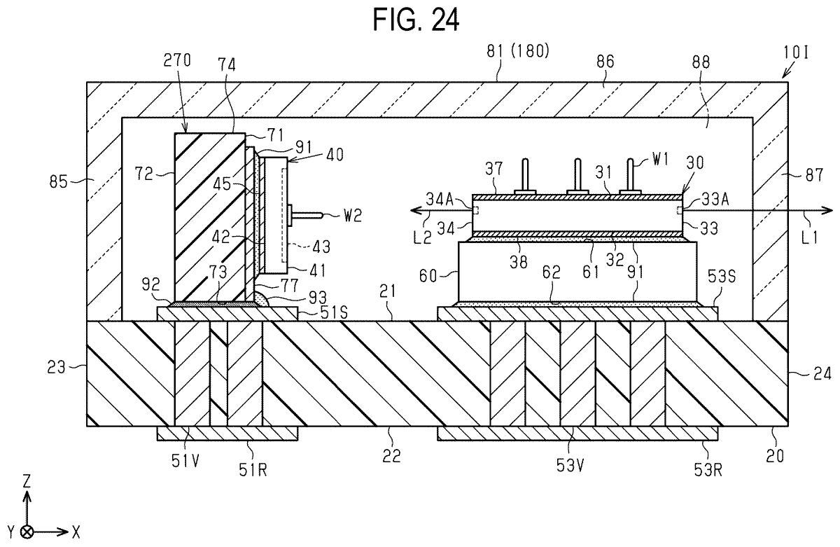

FIG. 24 is a cross-sectional view of a semiconductor light emitting device 10I according to a modification, and corresponds to the cross-sectional view of the semiconductor light emitting device 10 of the first embodiment shown in FIG. 2.

The semiconductor light emitting device 10I of the modification includes a cover member 180. The cover member 180 includes a main body 81 and a window member 87. The window member 87 is an integral member formed integrally with the main body 81. The cover member 180 may accommodate the edge light emitting element 30, the light receiving element 40, and the like.

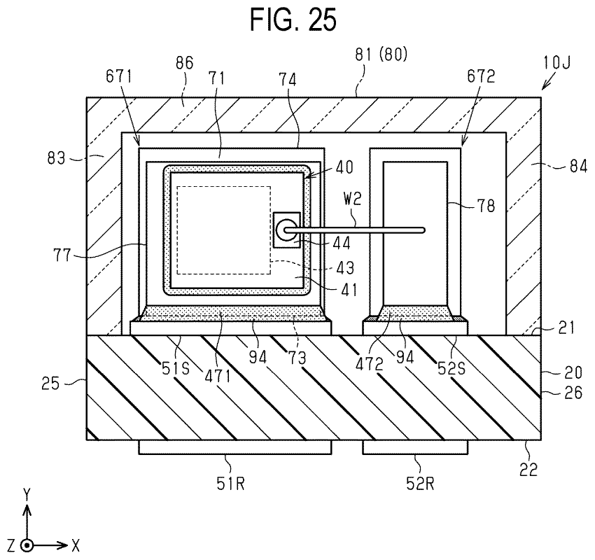

FIG. 25 is a cross-sectional view of a semiconductor light emitting device 10J according to a modification, and corresponds to the cross-sectional view of the semiconductor light emitting device 10 of the first embodiment shown in FIG. 4.

The semiconductor light emitting device 10J of the modification includes a first light receiving sub-mount 671 and a second light receiving sub-mount 672. The first light receiving sub-mount 671 is disposed over the first front surface electrode 51S. The first light receiving sub-mount 671 includes the first mounting electrode 77, and the light receiving element 40 is mounted thereon. The second light receiving sub-mount 672 is disposed over the second front surface electrode 52S. The second light receiving sub-mount 672 includes the second mounting electrode 78. The wire W2 connected to the first light receiving electrode 44 of the light receiving element 40 is connected to the second mounting electrode 78 of the second light receiving sub-mount 672.

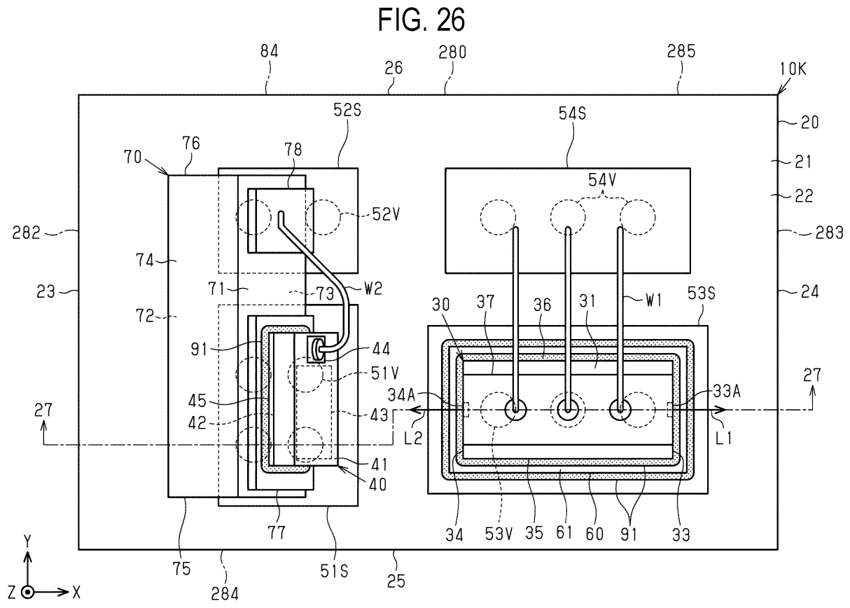

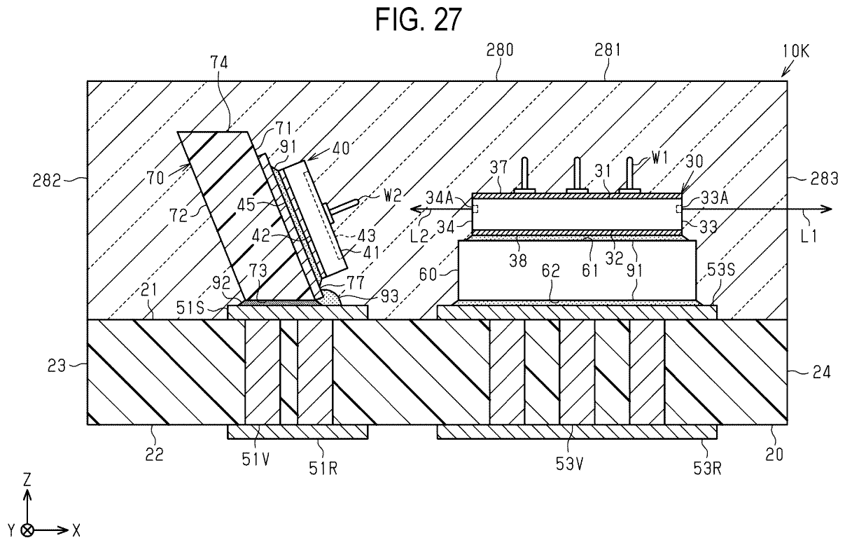

FIG. 26 is a schematic plan view of a semiconductor light emitting device 10K according to a modification. FIG. 27 is a schematic cross-sectional view of the semiconductor light emitting device 10K taken along line 27-27 in FIG. 26.

The semiconductor light emitting device 10K of the modification includes a sealing member 280 that seals the edge light emitting element 30 and the light receiving element 40. The sealing member 280 may seal at least a portion of the light receiving element 40 and at least a portion of the edge light emitting element 30.

As shown in FIG. 27, the sealing member 280 is provided over the substrate 20. The sealing member 280 is formed of a material through which the first laser beam L1 and the second laser beam L2 of the edge light emitting element 30 can pass. The sealing member 280 may be formed of, for example, a material containing at least one selected from the group of a silicone resin, an epoxy resin, and an acrylic resin. In one example, the sealing member 280 is formed of a silicone resin. In the semiconductor light emitting device 10K of the modification, the sealing member 280 seals the entire light receiving element 40 and the entire edge light emitting element 30.

The sealing member 280 is formed in a substantially rectangular flat plate shape with the Z direction being a thickness direction. The sealing member 280 includes a sealing front surface 281 facing the same side as the substrate front surface 21, and first to fourth sealing side surfaces 282 to 285 that intersect the sealing front surface 281. The sealing front surface 281 is a flat surface orthogonal to the thickness direction (Z direction) of the substrate 20. The first to fourth sealing side surfaces 282 to 285 are orthogonal to the sealing front surface 281, for example. The first sealing side surface 282 and the second sealing side surface 283 constitute both end surfaces of the sealing member 280 in the X direction, and the third sealing side surface 284 and the fourth sealing side surface 285 constitute both end surfaces of the sealing member 280 in the Y direction. The first sealing side surface 282 faces the same side as the first substrate side surface 23, and the second sealing side surface 283 faces the same side as the second substrate side surface 24. The third sealing side surface 284 faces the same side as the third substrate side surface 25, and the fourth sealing side surface 285 faces the same side as the fourth substrate side surface 26. In one example, the first sealing side surface 282 and the first substrate side surface 23 are formed to be flush with each other. The second sealing side surface 283 and the second substrate side surface 24 are formed to be flush with each other. The third sealing side surface 284 and the third substrate side surface 25 are formed to be flush with each other. The fourth sealing side surface 285 and the fourth substrate side surface 26 are formed to be flush with each other.

The second sealing side surface 283 of the sealing member 280 faces the X direction, which is the same direction as the first element end surface 33 of the edge light emitting element 30. The first laser beam L1 of the edge light emitting element 30 passes through the sealing member 280 and is emitted to an outside from the second sealing side surface 283. In the semiconductor light emitting device 10K of the modification, the edge light emitting element 30 and the light receiving element 40 are sealed by the sealing member 280. Therefore, it is possible to suppress foreign substances such as moisture and dust from adhering to the edge light emitting element 30 and the light receiving element 40.

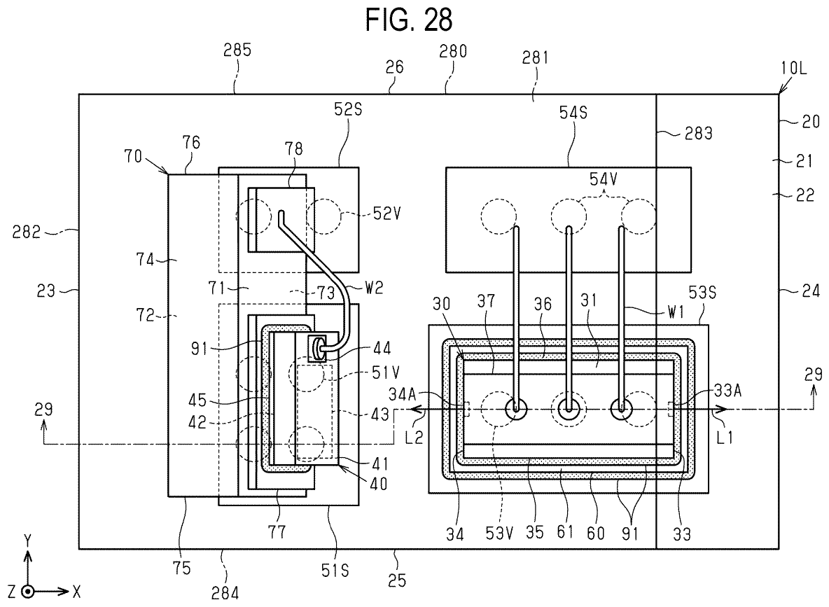

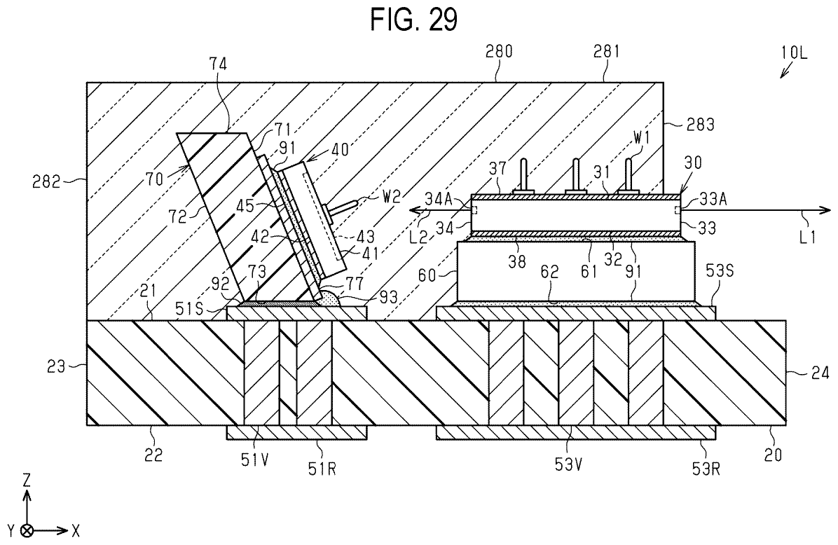

FIG. 28 is a schematic plan view of a semiconductor light emitting device 10L according to a modification. FIG. 29 is a schematic cross-sectional view of the semiconductor light emitting device 10L taken along line 29-29 in FIG. 28.

In the semiconductor light emitting device 10L of the modification, the sealing member 280 is formed to expose the first element end surface 33 of the edge light emitting element 30.

The second sealing side surface 283 of the sealing member 280 is located between the first element end surface 33 and the second element end surface 34 of the edge light emitting element 30 in the X direction. As a result, the first element end surface 33 of the edge light emitting element 30 is exposed from the sealing member 280. On the other hand, the second element end surface 34 of the edge light emitting element 30 is sealed with the sealing member 280. The light receiving element 40 is sealed with the sealing member 280.

In the semiconductor light emitting device 10L of this modification, the first element end surface 33 of the edge light emitting element 30 is exposed from the sealing member 280. Therefore, an optical system such as a lens for condensing the first laser beam L1 emitted from the first element end surface 33 may be disposed close to the first element end surface 33.

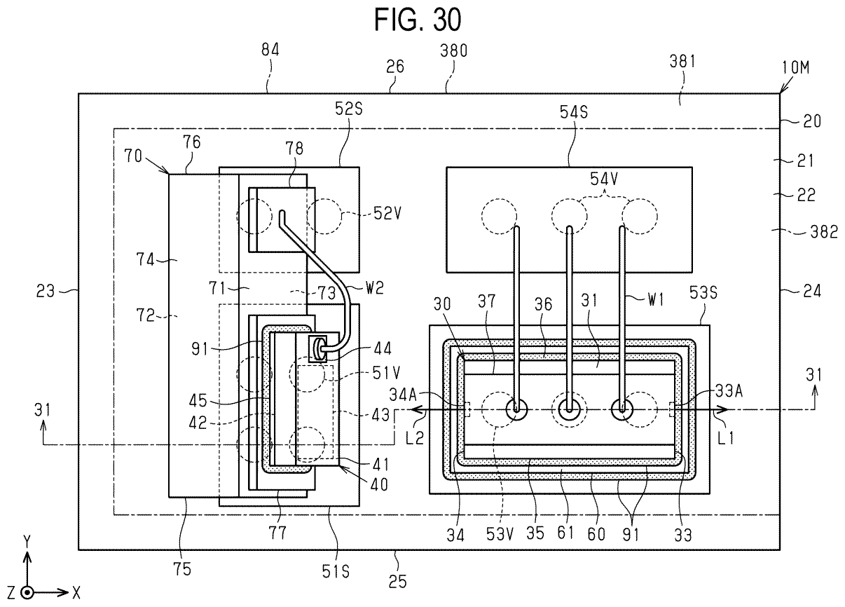

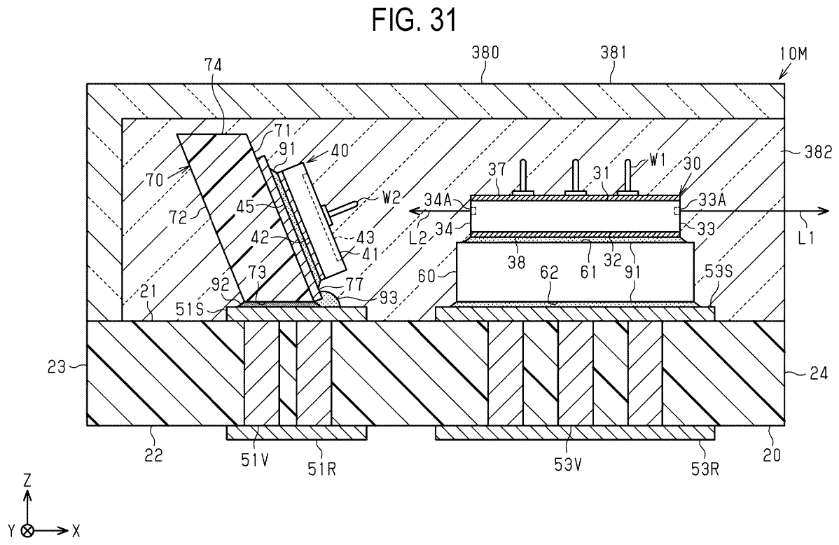

FIG. 30 is a schematic plan view of a semiconductor light emitting device 10M according to a modification. FIG. 31 is a schematic cross-sectional view of the semiconductor light emitting device 10M taken along line 31-31 in FIG. 30.

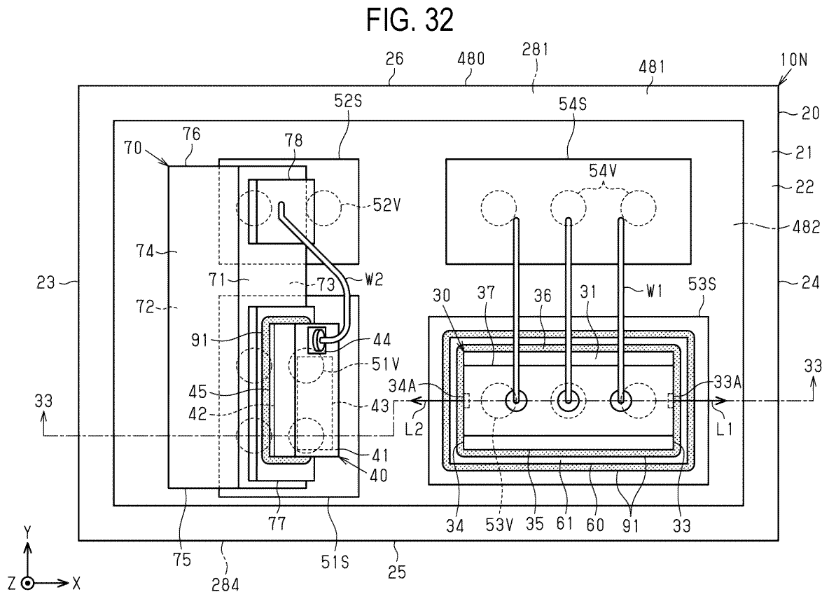

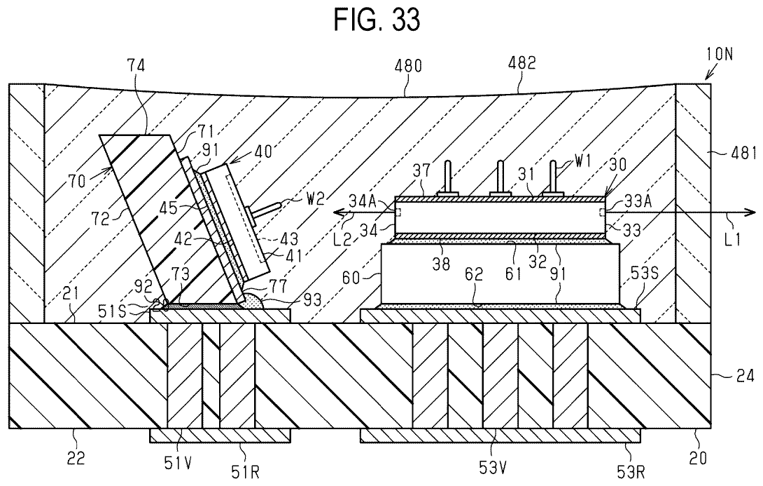

The semiconductor light emitting device 10M of the modification includes a sealing member 380. The sealing member 380 includes a cover member 381 and a sealing resin 382. The cover member 381 is configured similarly to the main body 81 shown in FIGS. 1 and 2. A region surrounded by the cover member 381 and the substrate 20 is filled with the sealing resin 382. The sealing resin 382 may be formed of, for example, a material containing at least one selected from the group of a silicone resin, an epoxy resin, and an acrylic resin. FIG. 32 is a schematic plan view of a semiconductor light emitting device 10N according to a modification. FIG. 33 is a schematic cross-sectional view of the semiconductor light emitting device 10N taken along line 33-33 in FIG. 32.

The semiconductor light emitting device 10N of the modification includes a sealing member 480. The sealing member 480 includes a main body 481 and a sealing resin 482. The main body 481 is provided over the substrate front surface 21 and is formed to surround the edge light emitting element 30, the light receiving element 40, and the light receiving sub-mount 70. The main body 481 is formed in a frame shape that opens toward an opposite side of the substrate 20 in the Z direction. In one example, the main body 481 is formed in a frame shape along the substrate side surfaces 23 to 26 of the substrate 20. The main body 481 may be formed of a material that is transparent to the first laser beam L1 emitted from the edge light emitting element 30. The main body 481 may be formed of a glass material, or a resin material such as a silicone resin, an epoxy resin, or an acrylic resin.

The sealing resin 482 is filled inside the main body 481. The sealing resin 482 seals the edge light emitting element 30 and the light receiving element 40. The sealing resin 482 may be formed of a material containing at least one selected from the group of a silicone resin, an epoxy resin, and an acrylic resin, for example. A resin upper surface of the sealing resin 482 may be flush with an upper end surface of the main body 481. Further, the resin upper surface of the sealing resin 482 may be recessed toward the substrate 20.

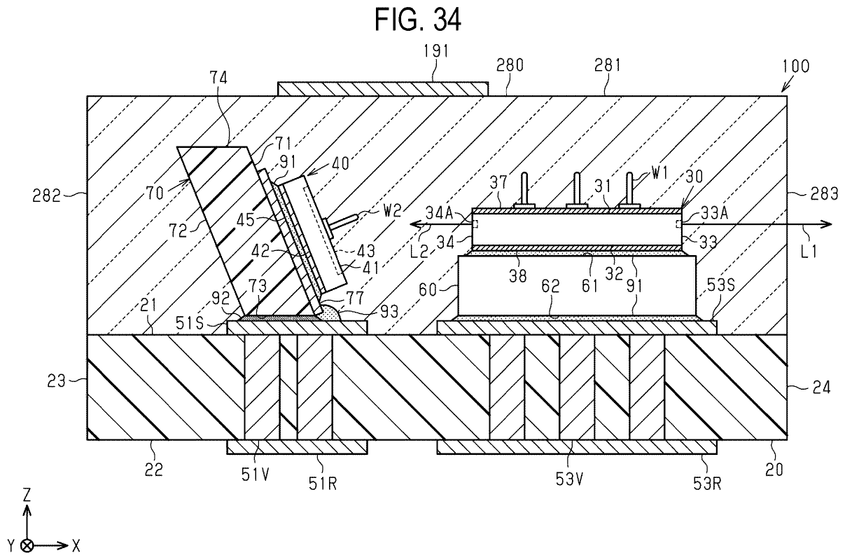

FIG. 34 is a schematic cross-sectional view of a semiconductor light emitting device 100 according to a modification.

The semiconductor light emitting device 100 of the modification includes the sealing member 280 and a light shielding layer 191 provided over the sealing front surface 281 of the sealing member 280. The light shielding layer 191 is formed to cover a portion of the sealing front surface 281. The light shielding layer 191 may be formed to cover the light receiving portion 43 of the light receiving element 40 in a plan view. The light shielding layer 191 may further be formed to cover an end portion of the edge light emitting element 30 that includes the second element end surface 34. The light shielding layer 191 may be formed of, for example, a resin material having a light shielding property. For example, a black epoxy resin is used as the resin material having a light shielding property. The light shielding layer 191 may be formed of, for example, a metal film. The light shielding layer 191 may be formed of an anti-reflection coat (AR coat). The shape of the light shielding layer 191 may be changed arbitrarily. This light shielding layer 191 suppresses light from outside the semiconductor light emitting device 100 from entering the light receiving portion 43 of the light receiving element 40.

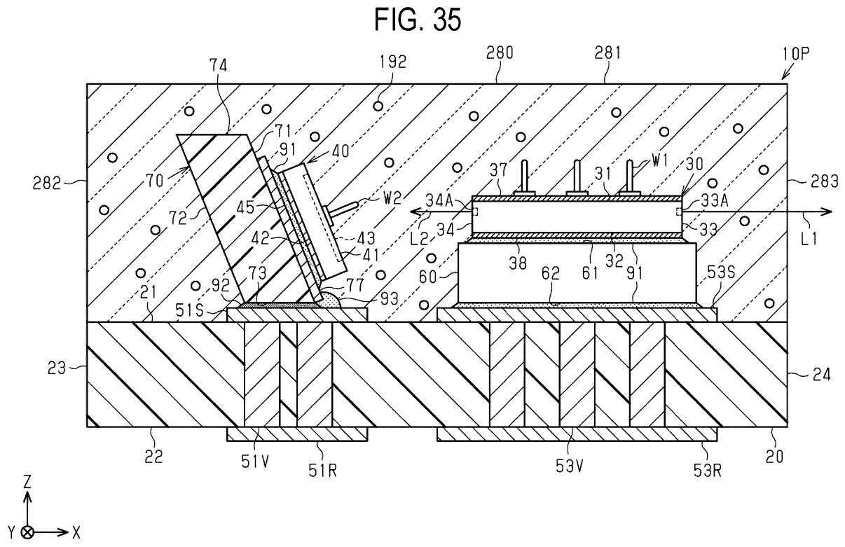

FIG. 35 is a schematic cross-sectional view of a semiconductor light emitting device 10P according to a modification.

The sealing member 280 of the semiconductor light emitting device 10P of the modification includes a diffusion material 192. The diffusion material 192 diffuses light inside the sealing member 280 by reflecting (scattering) the light at an interface between the resin in the sealing member 280 and the diffusion material 192. A material of the diffusion material 192 is not particularly limited, and may be, for example, silica or other glass materials. In one example, spherical silica filler is used as the diffusion material 192. A particle size of the diffusion material 192 is not particularly limited, and for example, a particle size which is sufficiently small with respect to wavelengths of the first laser beam L1 and the second laser beam L2 emitted from the edge light emitting element 30 is selected so that scattering occurs dominantly.

The diffusion material 192 is dispersed in the sealing member 280 as fine particles. The diffusion material 192 is mixed with the sealing member 280 at a predetermined mixing ratio. In one example, the diffusion material 192 is evenly distributed within the sealing member 280. The mixing ratio of the diffusion material 192 to the resin of the sealing member 280 is not particularly limited, and may be greater than 0% and less than 100%. The larger the mixing ratio of the diffusion material 192 is, the easier it is for the light receiving element 40 to receive scattered light. This makes it possible to widen a directivity angle of the first laser beam L1 of the edge light emitting element 30. Further, by limiting an upper limit of the mixing ratio of the diffusion material 192 to a predetermined value, it is possible to suppress a large decrease in the output and radiation intensity of the laser beam (first laser beam) of the semiconductor light emitting device 10P. In one example, a material having a coefficient of thermal expansion smaller than that of the resin of the sealing member 280 is selected as the diffusion material 192.

### Tenth Embodiment

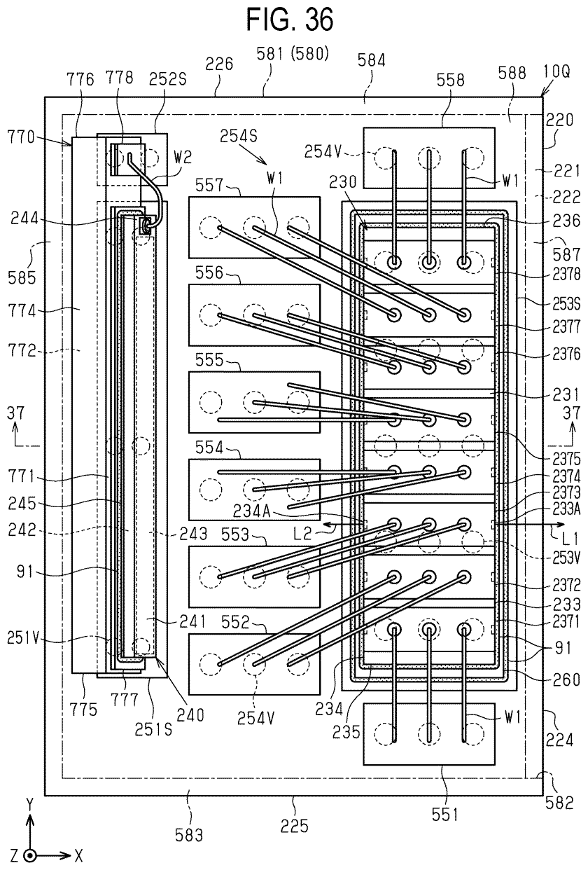

A semiconductor light emitting device 10Q according to a tenth embodiment is described with reference to FIGS. 36 to 38.

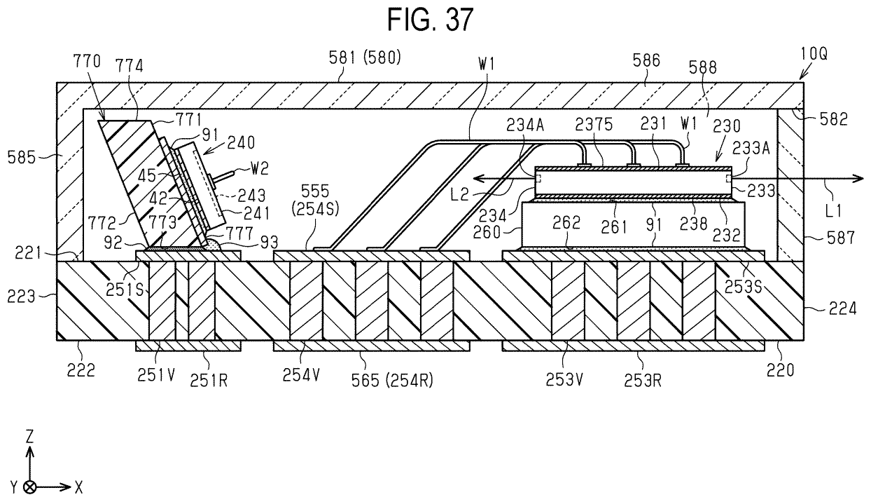

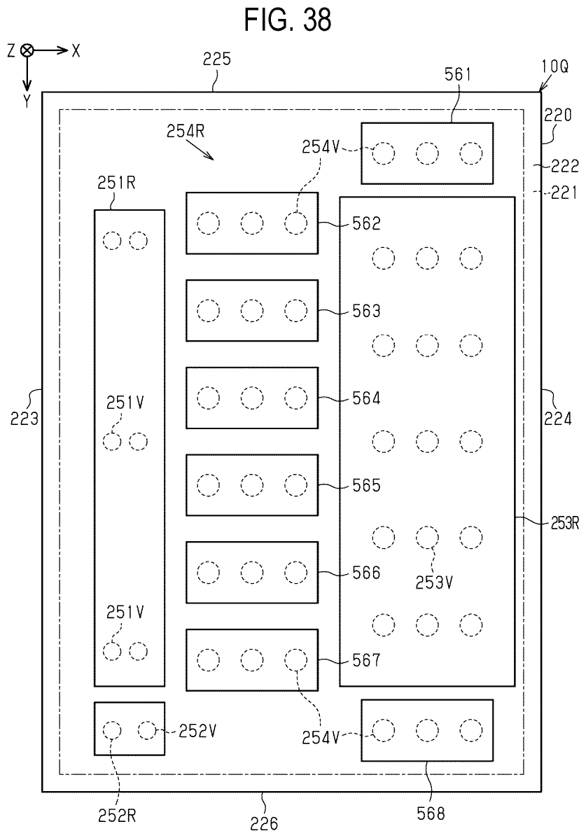

FIG. 36 is a schematic plan view of the semiconductor light emitting device 10Q according to the tenth embodiment. FIG. 37 is a schematic cross-sectional view of the semiconductor light emitting device 10Q taken along line 37-37 in FIG. 36. FIG. 38 is a schematic rear view of the semiconductor light emitting device 10Q shown in FIG. 36.

### Schematic Configuration of Semiconductor Light Emitting Device

As shown in FIGS. 36 to 38, the semiconductor light emitting device 10Q includes a substrate 220, an edge light emitting element 230 disposed over the substrate 220, and a light receiving element 240 disposed over the substrate 220. The semiconductor light emitting device 10Q includes a light receiving sub-mount 770 on which the light receiving element 240 is mounted. The semiconductor light emitting device 10Q may include a light emitting sub- mount 260 on which the edge light emitting element 230 is mounted. Further, the semiconductor light emitting device 10Q may include a cover member 580 that accommodates at least a portion of the edge light emitting element 230 and at least a portion of the light receiving element 240.

### Substrate

The substrate 220 is a component that supports the edge light emitting element 230 and the light receiving element 240. The substrate 220 is formed in a rectangular flat plate shape with the Z direction being a thickness direction.

The substrate 220 is formed in a rectangular shape in which the length thereof in the Y direction is longer than the length thereof in the X direction in a plan view. The substrate 220 includes a substrate front surface 221, a substrate back surface 222 opposite to the substrate front surface 221 in the Z direction, and first to fourth substrate side surfaces 223 to 226 that connect the substrate front surface 221 and the substrate back surface 222. The first substrate side surface 223 and the second substrate side surface 224 constitute both end surfaces of the substrate 220 in the X direction, and the third substrate side surface 225 and the fourth substrate side surface 226 constitute both end surfaces of the substrate 220 in the Y direction. The shape of the substrate 220 in a plan view may be changed arbitrarily.

The substrate 220 is formed of, for example, an insulating material. The substrate 220 may be formed of, for example, a resin material containing an epoxy resin. The resin material may contain fillers such as glass, ceramics, or the like. Further, the substrate 220 may be formed of, for example, a material containing ceramics. Examples of the material containing ceramics include aluminum nitride, alumina, or the like. The substrate 220 formed of the material containing ceramics has high heat dissipation performance and is capable of suppressing a temperature of the semiconductor light emitting device 10Q from becoming excessively high.

### Front Surface Electrode and Back Surface Electrode

As shown in FIGS. 36 and 37, the semiconductor light emitting device 10Q includes front surface electrodes 251S to 254S provided over the substrate front surface 221. The front surface electrodes 251S to 254S are formed of, for example, a material containing one or more components appropriately selected from Ti, TiN, Au, Ag, Cu, Al, and W.

As shown in FIG. 36, the first front surface electrode 251S is disposed closer to the first substrate side surface 223 than a center of the substrate front surface 221 in the X direction in a plan view. Further, the first front surface electrode 251S is disposed at a center of the substrate front surface 221 in the Y direction. In one example, the first front surface electrode 251S is formed in a rectangular shape in which the length thereof in the Y direction is longer than the length thereof in the X direction in a plan view. The disposed position and shape of the first front surface electrode 251S on the substrate front surface 221 may be changed arbitrarily.

The second front surface electrode 252S is spaced apart from the first front surface electrode 251S. The second front surface electrode 252S is spaced apart from the first front surface electrode 251S in the Y direction in a plan view. The second front surface electrode 252S is disposed closer to the first substrate side surface 223 than the center of the substrate front surface 221 in the X direction in a plan view. Further, the second front surface electrode 252S is disposed closer to the fourth substrate side surface 226 than the center of the substrate front surface 221 in the Y direction. It may be said that the second front surface electrode 252S is disposed between the first front surface electrode 251S and the fourth substrate side surface 226. In one example, the second front surface electrode 252S is formed in a rectangular shape in which the length thereof in the Y direction is shorter than the length thereof in the X direction in a plan view. The disposed position and shape of the second front surface electrode 252S on the substrate front surface 221 may be changed arbitrarily.

The third front surface electrode 253S is spaced apart from the first front surface electrode 251S. The third front surface electrode 253S is spaced apart from the first front surface electrode 251S in the X direction in a plan view. The third front surface electrode 253S is disposed closer to the second substrate side surface 224 than the center of the substrate front surface 221 in the X direction in a plan view. Further, the third front surface electrode 253S is disposed at the center of the substrate front surface 221 in the Y direction. In one example, the third front surface electrode 253S is formed in a rectangular shape in which the length thereof in the Y direction is longer than the length thereof in the X direction in a plan view. The disposed position and shape of the third front surface electrode 253S on the substrate front surface 221 may be changed arbitrarily.

The semiconductor light emitting device 10Q includes a plurality of fourth front surface electrodes 254S. In one example, the semiconductor light emitting device 10Q includes eight fourth front surface electrodes 254S. The number of fourth front surface electrodes 254S may be changed depending on the configuration of the edge light emitting element 230.

In order to distinguish the plurality of fourth front surface electrodes 254S, they are referred to as first to eighth auxiliary electrodes 551 to 558. It may be said that the plurality of fourth front surface electrodes 254S include the first to eighth auxiliary electrodes 551 to 558.

The first to eighth auxiliary electrodes 551 to 558 are spaced apart from the third front surface electrode 253S. The first to eighth auxiliary electrodes 551 to 558 are disposed so as to surround the third front surface electrode 253S in a plan view.

The first auxiliary electrode 551 is spaced apart from the third front surface electrode 253S in the Y direction. The first auxiliary electrode 551 is disposed closer to the third substrate side surface 225 in the Y direction of the substrate front surface 221. It may be said that the first auxiliary electrode 551 is disposed between the third front surface electrode 253S and the third substrate side surface 225.

The second to seventh auxiliary electrodes 552 to 557 are spaced apart from the third front surface electrode 253S in the X direction. The second to seventh auxiliary electrodes 552 to 557 are disposed between the third front surface electrode 253S and the first front surface electrode 251S. The light receiving sub-mount 770 is disposed over the first front surface electrode 251S, and the edge light emitting element 230 is disposed over the third front surface electrode 253S. It may be said that the second to seventh auxiliary electrodes 552 to 557 are disposed between the light receiving sub-mount 770 and the edge light emitting element 230 in a plan view. The second to seventh auxiliary electrodes 552 to 557 correspond to “a plurality of intermediate electrodes.”

The eighth auxiliary electrode 558 is spaced apart from the third front surface electrode 253S in the Y direction. The eighth auxiliary electrode 558 is disposed closer to the fourth substrate side surface 226 in the Y direction of the substrate front surface 221. It may be said that the eighth auxiliary electrode 558 is disposed between the third front surface electrode 253S and the fourth substrate side surface 226.

In one example, the first to eighth auxiliary electrodes 551 to 558 are formed in a rectangular shape in which the length thereof in the Y direction is shorter than the length thereof in the X direction in a plan view. The positions and shapes of the first to eighth auxiliary electrodes 551 to 558 on the substrate front surface 221 may be changed arbitrarily.

As shown in FIGS. 37 and 38, the semiconductor light emitting device 10Q includes back surface electrodes 251R to 254R provided over the substrate back surface 222. The back surface electrodes 251R to 254R are formed of, for example, a material containing one or more components appropriately selected from Ti, TiN, Au, Ag, Cu, Al, and W.

As shown in FIG. 38, the first back surface electrode 251R is disposed closer to the first substrate side surface 223 than a center of the substrate back surface 222 in the X direction in a plan view. Further, the first back surface electrode 251R is disposed at a center of the substrate back surface 222 in the Y direction. In one example, the first back surface electrode 251R is formed in a rectangular shape in which the length thereof in the Y direction is longer than the length thereof in the X direction in a plan view. In one example, the first back surface electrode 251R is formed to have the same size as the first front surface electrode 251S shown in FIG. 36. The disposed position and shape of the first back surface electrode 251R on the substrate back surface 222 may be changed arbitrarily.

The second back surface electrode 252R is spaced apart from the first back surface electrode 251R. The second back surface electrode 252R is spaced apart from the first back surface electrode 251R in the Y direction in a plan view. The second back surface electrode 252R is disposed closer to the first substrate side surface 223 than the center of the substrate back surface 222 in the X direction in a plan view. Further, the second back surface electrode 252R is disposed closer to the fourth substrate side surface 226 than the center of the substrate back surface 222 in the Y direction. It may be said that the second back surface electrode 252R is disposed between the first back surface electrode 251R and the fourth substrate side surface 226. In one example, the second back surface electrode 252R is formed in a rectangular shape in which the length thereof in the Y direction is shorter than the length thereof in the X direction in a plan view. In one example, the second back surface electrode 252R is formed to have the same size as the second front surface electrode 252S shown in FIG. 36. The disposed position and shape of the second back surface electrode 252R on the substrate back surface 222 may be changed arbitrarily.

The third back surface electrode 253R is spaced apart from the first back surface electrode 251R. The third back surface electrode 253R is spaced apart from the first back surface electrode 251R in the X direction in a plan view. The third back surface electrode 253R is disposed closer to the second substrate side surface 224 than the center of the substrate back surface 222 in the X direction in a plan view. Further, the third back surface electrode 253R is disposed at the center of the substrate back surface 222 in the Y direction. In one example, the third back surface electrode 253R is formed in a rectangular shape in which the length thereof in the Y direction is longer than the length thereof in the X direction in a plan view. In one example, the third back surface electrode 253R is formed to have the same size as the third front surface electrode 253S shown in FIG. 36. The disposed position and shape of the third back surface electrode 253R on the substrate back surface 222 may be changed arbitrarily.

The semiconductor light emitting device 10Q includes a plurality of fourth back surface electrodes 254R. In one example, the semiconductor light emitting device 10Q includes eight fourth back surface electrodes 254R. The number of fourth back surface electrodes 254R may be set to correspond to the number of fourth front surface electrodes 254S.

First to eighth auxiliary electrodes 561 to 568 are used to distinguish the plurality of fourth back surface electrodes 254R. It may be said that the plurality of fourth back surface electrodes 254R include the first to eighth auxiliary electrodes 561 to 568.

The first auxiliary electrode 561 is spaced apart from the third back surface electrode 253R in the Y direction. The first auxiliary electrode 561 is disposed closer to the third substrate side surface 225 in the Y direction of the substrate front surface 221. It may be said that the first auxiliary electrode 561 is disposed between the third back surface electrode 253R and the third substrate side surface 225.

The second to seventh auxiliary electrodes 562 to 567 are spaced apart from the third back surface electrode 253R in the X direction. The second to seventh auxiliary electrodes 562 to 567 are disposed between the third back surface electrode 253R and the first back surface electrode 251R.

The eighth auxiliary electrode 568 is spaced apart from the third back surface electrode 253R in the Y direction. The eighth auxiliary electrode 568 is disposed closer to the fourth substrate side surface 226 in the Y direction of the substrate front surface 221. It may be said that the eighth auxiliary electrode 568 is disposed between the third back surface electrode 253R and the fourth substrate side surface 226.

In one example, the first to eighth auxiliary electrodes 561 to 568 are formed in a rectangular shape in which the length thereof in the Y direction is shorter than the length thereof in the X direction in a plan view. The positions and shapes of the first to eighth auxiliary electrodes 561 to 568 on the substrate back surface 222 may be changed arbitrarily.

As shown in FIGS. 36 to 38, the semiconductor light emitting device 10Q includes vias 251V to 254V provided in the substrate 220. In FIGS. 36 and 38, the vias 251V to 254V are indicated by broken lines. The vias 251V to 254V may be formed of, for example, a material containing one or more components appropriately selected from Ti, TiN, Au, Ag, Cu, Al, and W.

The vias 251V to 254V penetrate the substrate 220 in the Z direction. The first via 251V electrically connects the first front surface electrode 251S and the first back surface electrode 251R. The second via 252V electrically connects the second front surface electrode 252S and the second back surface electrode 252R. The third via 253V electrically connects the third front surface electrode 253S and the third back surface electrode 253R. The fourth via 254V electrically connects the fourth front surface electrode 254S and the fourth back surface electrode 254R. The number of each of the vias 251V to 254V may be changed as appropriate.

### Light Emitting Sub-Mount

As shown in FIGS. 36 and 37, the light emitting sub-mount 260 is formed in a rectangular flat plate shape with the Z direction being a thickness direction. The light emitting sub-mount 260 is formed of, for example, a conductive material. As the conductive material, for example, Cu, Al, or the like is used. In one example, the light emitting sub-mount 260 is formed of Cu.

The light emitting sub-mount 260 includes a sub-mount front surface 261 and a sub-mount back surface 262 facing opposite sides to each other. The sub-mount front surface 261 faces the same side as the substrate front surface 221 of the substrate 220, and the sub-mount back surface 262 faces the same side as the substrate back surface 222 of the substrate 220.

The light emitting sub-mount 260 is electrically connected to the third front surface electrode 253S by the conductive bonding material 91. The conductive bonding material 91 is in contact with the sub-mount back surface 262. In a plan view, a dimension of the light emitting sub-mount 260 in the X direction is smaller than a dimension of the third front surface electrode 253S in the X direction, and a dimension of the light emitting sub-mount 260 in the Y direction is smaller than a dimension of the third front surface electrode 253S in the Y direction.

### Edge Light Emitting Element

The edge light emitting element 230 is spaced apart from the light receiving element 240 in the X direction. In one example, the edge light emitting element 230 is disposed at a position overlapping with the light receiving element 240 when viewed from the X direction. The edge light emitting element 230 is disposed closer to the second substrate side surface 224 than the light receiving element 240.

The edge light emitting element 230 is a laser diode that emits a laser beam in a predetermined wavelength band, and functions as a light source of the semiconductor light emitting device 10Q. For example, an edge light emitting type laser is used as the edge light emitting element 230. The wavelength band of the laser beam may be a visible light band, or may be a long wavelength band having a longer wavelength than visible light such as ultraviolet rays.

The edge light emitting element 230 is formed in a rectangular parallelepiped shape. In one example, the edge light emitting element 230 is formed in a rectangular shape in which the length thereof in the Y direction is longer than the length thereof in the X direction in a plan view. The shape of the edge light emitting element 230 in a plan view may be changed arbitrarily.

As shown in FIGS. 36 and 37, the edge light emitting element 230 includes a light emitting element front surface 231 and a light emitting element back surface 232 facing opposite sides to each other in the Z direction, a first element end surface 233 and a second element end surface 234 facing opposite sides to each other in the X direction, and element side surfaces 235 and 236 facing opposite sides to each other in the Y direction. The first element end surface 233 and the second element end surface 234, which constitute both end surfaces in the X direction, are configured by flat surfaces orthogonal to the light emitting element front surface 231 (light emitting element back surface 232). The first element end surface 233 and the second element end surface 234 face opposite sides to each other. The semiconductor light emitting device 10Q is configured to emit a first laser beam L1 from the first element end surface 233 in the X direction, which is an example of a first direction (X direction) intersecting the Z direction in a plan view. Further, the semiconductor light emitting device 10Q is configured to emit a second laser beam L2 from the second element end surface 234 in a direction opposite to the emission direction of the first laser beam L1.

As shown in FIG. 36, the edge light emitting element 230 includes eight first light emitting electrodes 2371 to 2378 formed over the light emitting element front surface 231, and one second light emitting electrode 238 formed over the light emitting element back surface 232. The edge light emitting element 230 includes emission regions 233A and 234A for each of the first light emitting electrodes 2371 to 2378. In a plan view, the plurality of first light emitting electrodes 2371 to 2378 are spaced apart in the Y direction. The plurality of emission regions 233A and 234A are arranged in the Y direction. The edge light emitting element 230 is configured to emit a laser beam from the plurality of emission regions 233A and 234A. In one example, the first light emitting electrodes 2371 to 2378 may form an anode, and the second light emitting electrode 238 may form a cathode. The first light emitting electrodes 2371 to 2378 and the second light emitting electrode 238 may be composed of a stacked structure of a plurality of conductive films.

The edge light emitting element 230 includes a semiconductor stacked structure composed of a plurality of semiconductor layers including a light emitting layer. The light emitting layer is composed of, for example, one or more active layers. The light emitting layer extends in the X direction. The edge light emitting element 230 is configured to emit a laser beam, which is generated from the light emitting layer by electric power supplied by the first light emitting electrodes 2371 to 2378 and the second light emitting electrode 238, from the first element end surface 233 and the second element end surface 234. It may be said that the first element end surface 233 and the second element end surface 234 include emission regions 233A and 234A from which the laser beams are emitted. In FIG. 36, the emission regions 233A and 234A of the first element end surface 233 and the second element end surface are clearly shown. In one example, the emission regions 233A and 234A are located closer to the light emitting element front surface 231 than a center in the thickness direction.

The edge light emitting element 230 is disposed over the light emitting sub-mount 260. The edge light emitting element 230 is bonded to the light emitting sub-mount 260 with the conductive bonding material 91. In one example, the edge light emitting element 230 is disposed with the second light emitting electrode 238 facing the sub-mount front surface 261 of the light emitting sub-mount 260. The second light emitting electrode 238 of the edge light emitting element 230 is electrically connected to the light emitting sub-mount 260 by the conductive bonding material 91. The conductive bonding material 91 is in contact with the sub-mount front surface 261.

As shown in FIG. 36, the edge light emitting element 230 is electrically connected to the first to eighth auxiliary electrodes 551 to 558. The first light emitting electrodes 2371 to 2378 of the edge light emitting element 230 are electrically connected to the first to eighth auxiliary electrodes 551 to 558 by a plurality of wires W1. The wires W1 are bonding wires formed by, for example, a wire bonding device, and are formed of a conductive material such as Au, Al, Cu, or the like.

### Light Receiving Sub-Mount

The semiconductor light emitting device 10Q includes a light receiving sub-mount 770 disposed over the substrate front surface 221 of the substrate 220. In one example, the light receiving sub-mount 770 is disposed over the first front surface electrode 251S.

In one example, the light receiving sub-mount 770 is formed in a rectangular flat plate shape. The light receiving sub-mount 770 is formed in a rectangular shape when viewed from the Y direction. In one example, the light receiving sub-mount 770 is formed in a parallelogram shape when viewed from the Y direction.

The light receiving sub-mount 770 includes a mounting surface 771 and a mounting back surface 772 facing opposite sides to each other in a thickness direction of the light receiving sub- mount 770, an attaching surface 773 and a top surface 774 facing opposite sides to each other in the Z direction, and side surfaces 775 and 776 facing opposite sides to each other in the Y direction. In one example, the mounting surface 771, the mounting back surface 772, the attaching surface 773, and the top surface 774 are formed in a rectangular shape, and the side surfaces 775 and 776 are formed in a parallelogram shape. The light receiving sub-mount 770 is disposed with the attaching surface 773 facing the substrate front surface 221 of the substrate 220.

As shown in FIG. 36, the light receiving sub-mount 770 is disposed so as to straddle the first front surface electrode 251S and the second front surface electrode 252S. The light receiving sub-mount 770 is disposed so that the mounting surface 771 faces the second element end surface 234 of the edge light emitting element 230. In one example, the light receiving sub-mount 770 is bonded to the first front surface electrode 251S and the second front surface electrode 252S using the adhesive 92. In one example, the adhesive 92 may contain an insulating resin material such as an epoxy resin or the like.

As shown in FIGS. 36 and 37, a first mounting electrode 777 and a second mounting electrode 778 are formed over the mounting surface 771. In one example, the first mounting electrode 777 and the second mounting electrode 778 are formed in a rectangular shape when viewed from a direction perpendicular to the mounting surface 771. In one example, the first mounting electrode 777 and the second mounting electrode 778 are formed over the mounting surface 771 to extend from an end near the mounting surface 773 toward an end near the top surface 774. The first mounting electrode 777 and the second mounting electrode 778 may be formed of, for example, a material containing one or more component appropriately selected from Ti, TiN, Au, Ag, Cu, Al, and W.

The first mounting electrode 777 is electrically connected to the first front surface electrode 251S by the conductive bonding material 93. The second mounting electrode 778 is electrically connected to the second front surface electrode 252S by the conductive bonding material 93.

The mounting surface 771 of the light receiving sub-mount 770 may extend along a direction intersecting the substrate front surface 221 when viewed from the Y direction. An angle of the mounting surface 771 with respect to the substrate front surface 221 may be determined by an angle between the mounting surface 771 of the light receiving sub-mount 770 and the attaching surface 773 facing the substrate front surface 221. The angle between the mounting surface 771 and the attaching surface 773 may be called an inclination angle of the mounting surface 771. The inclination angle may be 60 degrees or more and 90 degrees or less.

The light receiving sub-mount 770 of the tenth embodiment is formed such that the mounting surface 771 extends away from the second element end surface 234 as it extends away from the substrate front surface 221 in the X direction. The inclination angle of the light receiving sub-mount 770 of the tenth embodiment may be equal to or greater than 60 degrees and less than 90 degrees.

### Light Receiving Element

As shown in FIGS. 36 and 37, the light receiving element 240 is mounted on the light receiving sub-mount 770. The light receiving element 240 is mounted on the mounting surface 771 of the light receiving sub-mount 770.

The light receiving element 240 is formed in a rectangular flat plate shape. The light receiving element 240 includes a light receiving element front surface 241 and a light receiving element back surface 242 facing opposite sides to each other in a thickness direction. The light receiving element 240 is configured to receive a plurality of second laser beams L2 emitted from the plurality of emission regions 234A of the edge light emitting element 230.

The light receiving element 240 is, for example, a photodiode. The light receiving element 240 includes a light receiving portion 243. The light receiving portion 243 is formed at the light receiving element front surface 241. A formation range of the light receiving portion 243 is defined, for example, by a p-type well region formed in an n-type semiconductor substrate provided at the light receiving element 240. The light receiving element 240 further includes a first light receiving electrode 244 and a second light receiving electrode 245. The first light receiving electrode 244 is formed over the light receiving element front surface 241. Further, the second light receiving electrode 245 is formed over the light receiving element back surface 242. The first light receiving electrode 244 constitutes one of an anode and a cathode of the photodiode, and the second light receiving electrode 245 constitutes the other of the anode and the cathode of the photodiode. In the first embodiment, the first light receiving electrode 244 constitutes the anode, and the second light receiving electrode 245 constitutes the cathode. The light receiving element 240 is configured such that a current flows from the first light receiving electrode 244 to the second light receiving electrode 245 of the light receiving element 240 depending on an amount of light irradiated onto the light receiving portion 243.

The light receiving element 240 is bonded to the first mounting electrode 777 provided over the mounting surface 771 of the light receiving sub-mount 770. The light receiving element 240 is disposed with the second light receiving electrode 245 facing the first mounting electrode 777. The second light receiving electrode 245 is electrically connected to the first mounting electrode 777 by the conductive bonding material 91.

The first light receiving electrode 244 of the light receiving element 240 is electrically connected to the second mounting electrode 778 by a wire W2. In one example, a first end of the wire W2 is electrically connected to the first light receiving electrode 244, and a second end of the wire W2 is electrically connected to the second mounting electrode 778. The second end of the wire W2 may be electrically connected to the first light receiving electrode 244, and the first end of the wire W2 may be electrically connected to the second mounting electrode 778. The wire W2 is a bonding wire formed by, for example, a wire bonding device, and is formed of, for example, a conductive material such as Au, Al, Cu, or the like.

The light receiving portion 243 of the light receiving element 240 mounted on the light receiving sub-mount 770 faces the same direction as the mounting surface 771 of the light receiving sub-mount 770. The mounting surface 771 faces the second element end surface 234 of the edge light emitting element 230. Therefore, the light receiving portion 243 of the light receiving element 240 faces the second element end surface 234 of the edge light emitting element 230. The mounting surface 771 of the light receiving sub-mount 770 is formed so as to extend away from the second element end surface 234 as it extends away from the substrate front surface 221 in the Z direction. Therefore, it may be said that the light receiving element 240 is disposed such that the light receiving element front surface 241 extends away from the second element end surface 234 as it extends away from the substrate front surface 221 in the Z direction.

The light receiving sub-mount 770 is disposed such that the light receiving element front surface 241 of the light receiving element 240 mounted on the light receiving sub-mount 770 is spaced apart from the second element end surface 234 of the edge light emitting element 230 in the X direction. A distance D1 between the second element end surface 234 of the edge light emitting element 230 and the light receiving element front surface 241 of the light receiving element 240 is preferably 0.5 mm or more and 2.6 mm or less. The distance D1 is a distance in the X direction between a position on the light receiving element front surface 241 of the light receiving element 240, which is located at the same position as the emission region 234A of the second element end surface 234 in the Z direction, and the second element end surface 234 of the edge light emitting element 230.

### Cover Member

As shown in FIGS. 36, 37 and 38, the semiconductor light emitting device 10Q includes a cover member 580. The cover member 580 accommodates at least a portion of the edge light emitting element 230 and at least a portion of the light receiving element 240. The cover member 580 shown in FIG. 37 accommodates the entire edge light emitting element 230 and the entire light receiving element 240.

The cover member 580 is provided over the substrate 220. The cover member 580 is attached to the substrate front surface 221 of the substrate 220 by, for example, an adhesive. The semiconductor light emitting device 10Q includes a sealed space 588 formed between an inner surface of the cover member 580 and the substrate front surface 221 of the substrate 220. It may be said that the edge light emitting element 230 and the light receiving element 240 are disposed within the sealed space 588.

The cover member 580 is formed in a box shape that opens toward the substrate 220. The cover member 580 includes a main body 581. The main body 581 includes an opening 582 through which the laser beam emitted from the first element end surface 233 of the edge light emitting element 230 passes. The main body 581 includes side walls 583 and 584 extending along the substrate side surfaces 225 and 226 of the substrate 220, a side wall 585 extending along the substrate side surface 223 of the substrate 220, and an upper wall 586 that covers the edge light emitting element 230 and the light receiving element 240 in the Z direction. The side walls 583, 584, and 585 are formed in a flat plate shape extending along the substrate side surfaces 225, 226, and 223. The upper wall 586 is formed in a flat plate shape orthogonal to the Z direction.

The cover member 580 may include a window member 587 that closes the opening 582 of the main body 581. The window member 587 is formed to extend along the substrate side surface 224 of the substrate 220. The window member 587 is formed into a flat plate shape extending along the substrate side surface 224. The window member 587 is integrally formed with the main body 581. The window member 587 and the main body 581 may be integrated.

The main body 581 may be formed of a material that is transparent to the laser beam emitted from the edge light emitting element 230. The main body 581 may be formed of a glass material, or a resin material such as a silicone resin, an epoxy resin, an acrylic resin, or the like. The main body 581 may be formed of a material that blocks the laser beam emitted from the edge light emitting element 230. The main body 581 may be formed of a metal material, or a material containing ceramics.

### Effect

According to the semiconductor light emitting device 10Q of the tenth embodiment, the following effects are obtained.
(10-1) The same effects as those of the semiconductor light emitting device 10 of the first embodiment are obtained.
(10-2) The edge light emitting element 230 includes the plurality of emission regions 233A. Therefore, it is possible to increase a laser output of the semiconductor light emitting device 10Q.

### Eleventh Embodiment

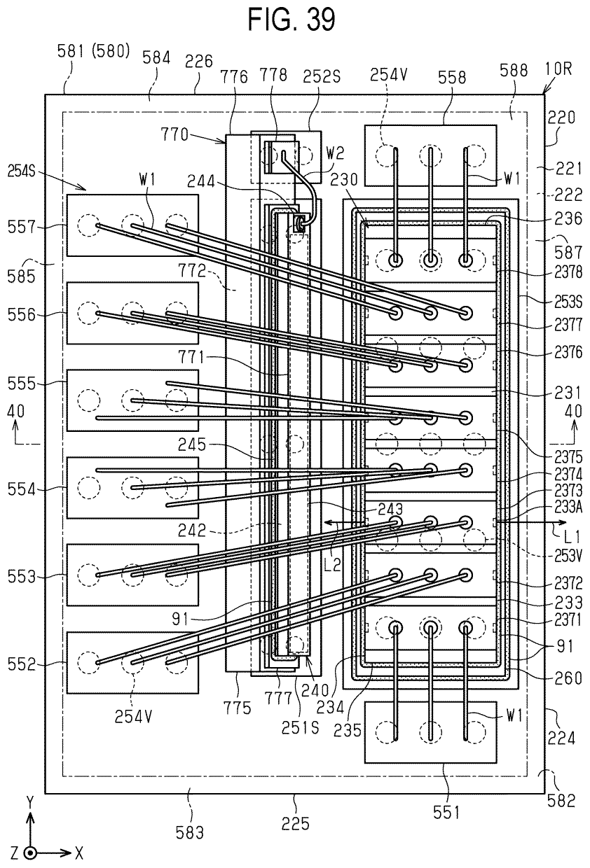

A semiconductor light emitting device 10R according to an eleventh embodiment is described with reference to FIGS. 39 to 41. The semiconductor light emitting device 10R of the eleventh embodiment differs from the semiconductor light emitting device 10Q of the tenth embodiment in the arrangement of the front surface electrodes. The points differing from the semiconductor light emitting device 10Q of the tenth embodiment are described below in detail. Further, the same components as those of the semiconductor light emitting device 10Q of the tenth embodiment are designated by like reference numerals, and the detailed description thereof is omitted.

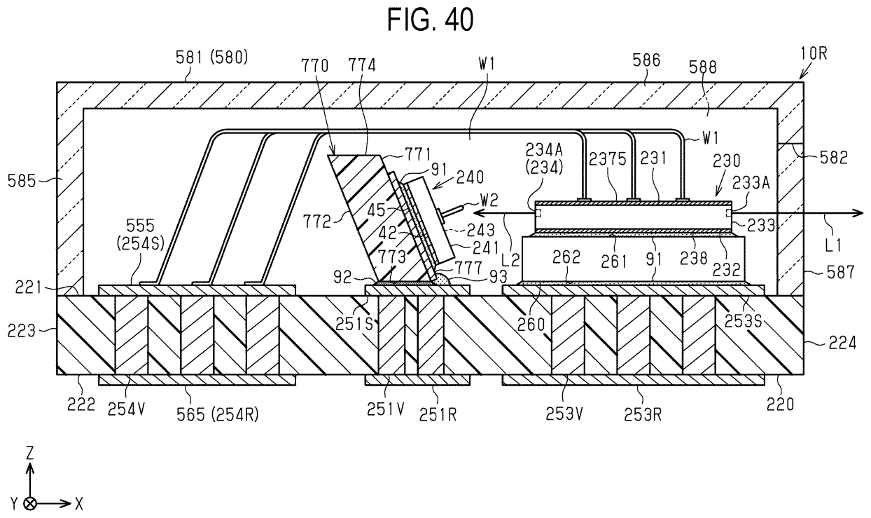

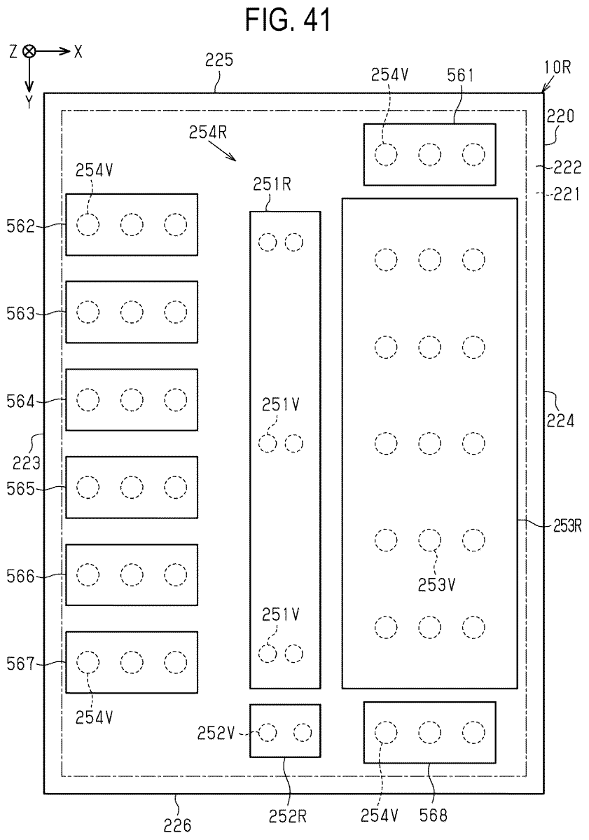

FIG. 39 is a schematic plan view of the semiconductor light emitting device 10R according to the eleventh embodiment. FIG. 40 is a schematic cross-sectional view of the semiconductor light emitting device 10R taken along line 40-40 in FIG. 39. FIG. 41 is a schematic rear view of the semiconductor light emitting device 10R shown in FIG. 39.

As shown in FIGS. 39 to 41, the semiconductor light emitting device 10R includes first to eighth auxiliary electrodes 551 to 558, which are a plurality of fourth front surface electrodes 254S. The second to seventh auxiliary electrodes 552 to 557 are disposed on an opposite side from the edge light emitting element 230 with respect to the first front surface electrode 251S. The second to seventh auxiliary electrodes 552 to 557 are disposed closer to the first substrate side surface 223 than the light receiving sub-mount 770 and the light receiving element 240. It may be said that the second to seventh auxiliary electrodes 552 to 557 are disposed so that the light receiving sub-mount 770 and the light receiving element 240 are sandwiched between the second to seventh auxiliary electrodes 552 to 557 and the edge light emitting element 230 in a plan view. The second to seventh auxiliary electrodes 552 to 557 correspond to “a plurality of end electrodes.”

As shown in FIGS. 39 and 40, the wires W1 that electrically connect the first light emitting electrodes 2372 to 2377 of the edge light emitting element 230 and the second to seventh auxiliary electrodes 552 to 557 are disposed so as to pass through an opposite side of the substrate 220 with respect to the light receiving sub-mount 770 and the light receiving element 240. The wires W1 that electrically connect the first light emitting electrodes 2372 to 2377 and the second to seventh auxiliary electrodes 552 to 557 are disposed so as to pass between the light receiving element 240 and the light receiving sub-mount 770 and the cover member 580, specifically between the light receiving element 240 and the light receiving sub-mount 770 and an upper wall 586 of the cover member 580.

### Operation

When the second to seventh auxiliary electrodes 552 to 557 are disposed between the edge light emitting element 230 and the light receiving element 240 as in the semiconductor light emitting device 10Q of the tenth embodiment, an amount of light incident on the light receiving element 240 may decrease or fluctuate depending on the state of the wires W1 connected to the second to seventh auxiliary electrodes 552 to 557. On the other hand, in the semiconductor light emitting device 10R of the eleventh embodiment, the wires W1 that electrically connect the first light emitting electrodes 2372 to 2377 of the edge light emitting element 230 and the second to seventh auxiliary electrodes 552 to 557 are disposed so as to pass through the opposite side of the substrate 220 with respect to the light receiving sub-mount 770 and the light receiving element 240. Therefore, it is possible to stabilize the amount of light incident on the light receiving element 240.

### Effect

According to the semiconductor light emitting device 10R of the eleventh embodiment, the following effects are obtained.
(11-1) The same effects as those of the semiconductor light emitting device 10Q of the tenth embodiment are obtained.
(11-2) In the semiconductor light emitting device 10R of the eleventh embodiment, the wires W2 that electrically connect the first light emitting electrodes 2372 to 2377 of the edge light emitting element 230 and the second to seventh auxiliary electrodes 552 to 557 are disposed so as to pass through the opposite side of the substrate 220 with respect to the light receiving sub-mount 770 and the light receiving element 240 in the Z direction. Therefore, it is possible to stabilize the amount of light incident on the light receiving element 240.

### Modification

The above-described embodiments may be modified as follows, for example. The above-described embodiments and each modification described below may be combined with each other as long as no technical contradiction occurs. In addition, in the following modifications, the parts common to the above-described embodiments are designated by the same reference numerals as in the above-described embodiments, and the description thereof is omitted.

In the tenth and eleventh embodiments, the number of emission regions included in one edge light emitting element may be changed as appropriate.

In contrast to the tenth and eleventh embodiments, a semiconductor light emitting device including a plurality of edge light emitting elements may be provided. For example, a semiconductor light emitting device may be configured by including a plurality of the edge light emitting elements 30 shown in the first embodiment. The number of edge light emitting elements may be an arbitrary number equal to or greater than two. The number of light emitting portions included in the edge light emitting elements may be an arbitrary number equal to or greater than two. For example, four edge light emitting elements including two light emitting portions may be mounted.

The composition of the substrate 20 may be changed as appropriate. The substrate 20 may be formed of a metal material such as Cu, Al, or the like. In this case, an insulating layer is formed over each of the front and back surfaces of a flat frame (e.g., a metal core) formed of Cu, Al, or the like. A plurality of front surface electrodes are formed over the insulating layer (substrate front surface 21) formed over the front surface of the frame. A plurality of back surface electrodes are formed over the insulating layer (substrate back surface 22) formed over the back surface of the frame. A plurality of through-wirings (vias) that individually and electrically connect the plurality of back surface electrodes and the plurality of front surface electrodes penetrate through the frame in its thickness direction thereof (Z direction). In this case, an insulating layer is formed over an inner surface of through-holes formed in the frame. The through-wirings are formed, for example, to fill spaces formed in the insulating layer. The same may be applied to the substrate 220 and the members related to the substrate 220.

In the above-described embodiment, the configurations of the substrate 20, the first to fourth front surface electrodes 51S to 54S, the first to fourth back surface electrodes 51R to 54R, and the first to fourth vias 51V to 54V may be changed arbitrarily. In one example, instead of the plurality of front surface electrodes, the plurality of back surface electrodes, and the plurality of vias, the semiconductor light emitting device may include a frame in which the front surface electrodes, the back surface electrodes, and the vias are integrated, and a substrate formed of an insulating material and configured to support the frame. In this case, a plurality of frames are provided to correspond to the plurality of front surface electrodes (the plurality of back surface electrodes). The substrate is formed of, for example, an epoxy resin such as an insulating material. The plurality of frames are provided so as to penetrate the substrate in the Z direction. Therefore, the plurality of frames exposed from the front surface of the substrate constitute a plurality of front surface electrodes, and the plurality of frames exposed from the back surface of the substrate constitute a plurality of back surface electrodes.

As used herein, terms such as “first,” “second,” and “third” are used merely to distinguish between objects, and are not intended to rank the objects. The expression “at least one” as used herein means “one or more” of desired options. As an example, the expression “at least one” as used herein means “only one option” or “both of two options” if the number of options is two. As another example, the expression “at least one” as used herein means “only one option” or “any combination of two or more options” if there are three or more options.

As used herein, the term “over” includes both “on” and “above” unless the context clearly dictates otherwise. Thus, the phrase “a first layer is formed over a second layer” means that in a certain embodiment, the first layer is directly disposed on the second layer in contact with the second layer, but in another embodiment, the first layer is disposed above the second layer without contacting the second layer. That is, the term “over” does not exclude a structure in which another layer is formed between the first layer and the second layer.

The Z-axis direction used herein does not necessarily have to be a vertical direction, nor does it need to completely coincide with the vertical direction. Accordingly, in various structures according to the present disclosure (e.g., the structure shown in FIG. 1), “upper” and “lower” in the Z-axis direction described herein are not limited to “upper” and “lower” in the vertical direction. For example, the X-axis direction may be a vertical direction, or the Y-axis direction may be a vertical direction.

### SUPPLEMENTARY NOTE

Technical ideas that may be understood from the present disclosure are described below. Not for the purpose of limitation but for the purpose of aiding understanding, the reference numerals of the corresponding components used in the embodiments are affixed to the components described in the supplementary notes. The reference numerals are indicated by way of example to aid understanding, and the components described in each supplementary note should not be limited to the components indicated by the reference numerals.

### Supplementary Note 1

A semiconductor light emitting device, including:
a substrate (20) including a substrate front surface (21);
an edge light emitting element (30) mounted on the substrate front surface (21), the edge light emitting element (30) including a first element end surface facing a first direction intersecting a thickness direction perpendicular to the substrate front surface (21) and a second element end surface facing an opposite direction to the first element end surface, the edge light emitting element (30) configured such that light is emitted from the first element end surface and the second element end surface;
a light receiving sub-mount (70) provided over the substrate front surface (21) and including a mounting surface facing the second element end surface; and
a light receiving element (40) mounted on the mounting surface and including a light receiving portion provided at a light receiving element front surface and facing the second element end surface.

### Supplementary Note 2

The semiconductor light emitting device of Supplementary Note 1, wherein the light receiving sub-mount (70) has an insulation property.

### Supplementary Note 3

The semiconductor light emitting device of Supplementary Note 1 or 2, wherein the light receiving sub-mount (70) is formed such that the mounting surface is perpendicular to the substrate front surface (21).

### Supplementary Note 4

The semiconductor light emitting device of Supplementary Note 1 or 2, wherein the light receiving sub-mount (70) is formed such that the mounting surface extends away from the second element end surface as the mounting surface extends away from the substrate front surface (21) in the thickness direction.

### Supplementary Note 5

The semiconductor light emitting device of Supplementary Note 4, wherein an angle of the mounting surface with respect to the substrate front surface (21) is 60 degrees or more and less than 90 degrees.

### Supplementary Note 6

The semiconductor light emitting device of any one of Supplementary Notes 1 to 5, wherein the substrate (20) includes a substrate back surface facing an opposite side to the substrate front surface (21),
wherein the semiconductor light emitting device further includes a first back surface electrode and a second back surface electrode provided over the substrate back surface, and
wherein the light receiving element (40) is electrically connected between the first back surface electrode and the second back surface electrode.

### Supplementary Note 7

The semiconductor light emitting device of Supplementary Note 6, wherein the light receiving element (40) includes a first light receiving electrode provided over the light receiving element (40) front surface, a light receiving element (40) back surface facing an opposite side to the light receiving element (40) front surface, and a second light receiving electrode provided over the light receiving element (40) back surface.

### Supplementary Note 8

The semiconductor light emitting device of Supplementary Note 6, wherein the light receiving element (40) includes a light receiving element (40) back surface facing an opposite side to the light receiving element (40) front surface, and a first light receiving electrode and a second light receiving electrode provided over the light receiving element (40) back surface.

### Supplementary Note 9

The semiconductor light emitting device of Supplementary Note 7 or 8, wherein the light receiving sub-mount (70) includes a first mounting electrode that is provided over the mounting surface and electrically connected to the first light receiving electrode, and a second mounting electrode that is provided over the mounting surface and electrically connected to the second light receiving electrode.

### Supplementary Note 10

The semiconductor light emitting device of Supplementary Note 9, further including:
a first front surface electrode provided over the substrate front surface (21) and electrically connected to the first back surface electrode; and
a second front surface electrode provided over the substrate front surface (21) and electrically connected to the second back surface electrode,
wherein the first mounting electrode is electrically connected to the first front surface electrode, and
wherein the second mounting electrode is electrically connected to the second front surface electrode.

### Supplementary Note 11

The semiconductor light emitting device of Supplementary Note 10, wherein the light receiving sub-mount (70) is disposed to straddle the first front surface electrode and the second front surface electrode.

### Supplementary Note 12

The semiconductor light emitting device of Supplementary Note 10, wherein the light receiving sub-mount (70) is disposed over the substrate front surface (21) so as not to overlap with the first front surface electrode and the second front surface electrode when viewed from the thickness direction.

### Supplementary Note 13

The semiconductor light emitting device of any one of Supplementary Notes 10 to 12, further including:
a first wire configured to electrically connect the first light receiving electrode and the second mounting electrode.

### Supplementary Note 14

The semiconductor light emitting device of Supplementary Note 9, wherein the light receiving sub-mount (70) is integrally formed with the substrate (20).

### Supplementary Note 15

The semiconductor light emitting device of Supplementary Note 14, further including:
a first internal wiring and a second internal wiring provided inside the light receiving sub-mount (70) and the substrate (20),
wherein the first internal wiring is configured to electrically connect the first mounting electrode and the first back surface electrode, and
wherein the second internal wiring is configured to electrically connect the second mounting electrode and the second back surface electrode.

### Supplementary Note 16

The semiconductor light emitting device of Supplementary Note 14 or 15, wherein the light receiving sub-mount (70) and the substrate (20) are formed of ceramic.

### Supplementary Note 17

The semiconductor light emitting device of any one of Supplementary Notes 1 to 16, further including:
a third front surface electrode provided over the substrate front surface (21); and
a fourth front surface electrode provided over the substrate front surface (21) and spaced apart from the third front surface electrode,
wherein the edge light emitting element (30) is electrically connected to the third front surface electrode.

### Supplementary Note 18

The semiconductor light emitting device of Supplementary Note 17, wherein the substrate (20) includes a substrate back surface facing an opposite side to the substrate front surface (21), and further including:
a third back surface electrode provided over the substrate back surface and electrically connected to the third front surface electrode; and
a fourth back surface electrode provided over the substrate back surface and electrically connected to the fourth front surface electrode.

### Supplementary Note 19

The semiconductor light emitting device of Supplementary Note 17 or 18, wherein the edge light emitting element (30) includes:
a light emitting element front surface facing a same direction as the substrate front surface (21);
a light emitting element back surface facing an opposite direction to the light emitting element front surface;
a first light emitting electrode formed over the light emitting element front surface; and
a second light emitting electrode formed over the light emitting element back surface,
wherein the second light emitting electrode is electrically connected to the third front surface electrode.

### Supplementary Note 20

The semiconductor light emitting device of Supplementary Note 19, further including:
a second wire configured to electrically connect the first light emitting electrode and the fourth front surface electrode.

### Supplementary Note 21

The semiconductor light emitting device of Supplementary Note 19 or 20, further including:
a light emitting sub-mount disposed over the third front surface electrode,
wherein the edge light emitting element (30) is disposed over the light emitting sub- mount.

### Supplementary Note 22

The semiconductor light emitting device of Supplementary Note 21, wherein the light receiving element (40) is disposed such that an emission region of the second element end surface of the edge light emitting element (30) is located between both ends of the light receiving portion in the thickness direction.

### Supplementary Note 23

The semiconductor light emitting device of Supplementary Note 21 or 22, wherein the light emitting sub-mount is formed of a conductive material, and
wherein the second light emitting electrode is electrically connected to the third front surface electrode through the light emitting sub-mount.

### Supplementary Note 24

The semiconductor light emitting device of Supplementary Note 21 or 22, wherein the light emitting sub-mount includes a base formed of an insulating material, and a through-wiring formed of a conductive material and configured to penetrate the base, and
wherein the second light emitting electrode is electrically connected to the third front surface electrode through the through-wiring.

### Supplementary Note 25

The semiconductor light emitting device of any one of Supplementary Notes 19 to 24, wherein the edge light emitting element (30) includes a plurality of emission regions on the second element end surface and a plurality of the first light emitting electrodes provided over the light emitting element front surface.

### Supplementary Note 26

The semiconductor light emitting device of any one of Supplementary Notes 19 to 24, wherein the edge light emitting element (30) includes one emission region on the second element end surface,
wherein the semiconductor light emitting device further includes a plurality of the edge light emitting elements (30), and
wherein the edge light emitting elements (30) are disposed in a second direction intersecting the first direction when viewed from the thickness direction.

### Supplementary Note 27

The semiconductor light emitting device of Supplementary Note 25 or 26, wherein a plurality of the fourth front surface electrodes are provided over the substrate front surface (21), and
wherein the semiconductor light emitting device further includes a plurality of wires configured to electrically connect the plurality of first light emitting electrodes and the plurality of fourth front surface electrodes.

### Supplementary Note 28

The semiconductor light emitting device of Supplementary Note 27, wherein the fourth surface electrodes include a plurality of intermediate electrodes disposed between the edge light emitting element (30) and the light receiving sub-mount (70) when viewed from the thickness direction.

### Supplementary Note 29

The semiconductor light emitting device of Supplementary Note 27, wherein the fourth front surface electrodes include a plurality of end electrodes disposed to sandwich the light receiving sub-mount (70) and the light receiving element (40) between the end electrodes and the edge light emitting element (30) when viewed from the thickness direction, and
wherein wires electrically connecting the plurality of end electrodes and the first light emitting electrodes are disposed to pass through an opposite side to the substrate (20) with respect to the light receiving element (40) in the thickness direction.

### Supplementary Note 30

The semiconductor light emitting device of Supplementary Note 28 or 29, wherein the light receiving element (40) is configured to receive light emitted from the second element end surfaces of the plurality of the edge light emitting elements (30).

### Supplementary Note 31

The semiconductor light emitting device of Supplementary Note 28 or 29, further including:
a plurality of the light receiving elements (40) configured to receive light emitted from the plurality of the edge light emitting elements (30).

### Supplementary Note 32

The semiconductor light emitting device of any one of Supplementary Notes 1 to 31, wherein the edge light emitting element (30) is configured such that an output of light emitted from the second element end surface is smaller than an output of light emitted from the first element end surface.

### Supplementary Note 33

The semiconductor light emitting device of any one of Supplementary Notes 1 to 32, further including:
a cover member provided over the substrate front surface (21) and configured to accommodate the edge light emitting element (30) and the light receiving element (40).

### Supplementary Note 34

The semiconductor light emitting device of Supplementary Note 33, wherein the cover member includes a main body configured to accommodate the edge light emitting element (30) and the light receiving element (40) and including an opening through which a laser beam emitted from the first element end surface passes.

### Supplementary Note 35

The semiconductor light emitting device of Supplementary Note 34, wherein the cover member includes a window member configured to close the opening, and
wherein the window member is formed of a material that is transparent to the laser beam.

### Supplementary Note 36

The semiconductor light emitting device of Supplementary Note 34 or 35, wherein the main body is formed of a material having a light blocking property.

### Supplementary Note 37

The semiconductor light emitting device of Supplementary Note 34 or 35, wherein the main body is formed of a material having a light transmitting property.

### Supplementary Note 38

The semiconductor light emitting device of any one of Supplementary Notes 1 to 32, further including:
a sealing member configured to seal at least a portion of the edge light emitting element (30) and the light receiving element (40).

### Supplementary Note 39

The semiconductor light emitting device of Supplementary Note 38, wherein the first element end surface is exposed from the sealing member.

### Supplementary Note 40

The semiconductor light emitting device of Supplementary Note 38 or 39, wherein the sealing member is formed of a material that blocks light in a wavelength range including visible light, and
wherein the edge light emitting element (30) is configured to emit light in a wavelength range that passes through the sealing member.

### Supplementary Note 41

The semiconductor light emitting device of any one of Supplementary Notes 38 to 40, wherein the sealing member includes a sealing surface facing a same side as the substrate front surface (21), and
wherein a light shielding layer is provided between the second element end surface and the light receiving element (40) front surface on the sealing surface when viewed from the thickness direction.

### Supplementary Note 42

The semiconductor light emitting device of any one of Supplementary Notes 38 to 41, further including:
a plurality of diffusion materials provided in the sealing member and configured to diffuse a laser beam emitted by the edge light emitting element (30).

### Supplementary Note 43

The semiconductor light emitting device of Supplementary Note 38, wherein the sealing member includes a frame-shaped main body provided over the substrate front surface (21) and configured to surround the edge light emitting element (30) and the light receiving element (40), and a sealing resin accommodated in the main body and configured to seal the edge light emitting element (30) and the light receiving element (40).

### Supplementary Note 44

The semiconductor light emitting device of any one of Supplementary Notes 1 to 43, wherein a distance in the first direction between the second element end surface and the light receiving element (40) front surface is 0.5 mm or more and 2.6 mm or less.

### Supplementary Note 45

The semiconductor light emitting device of any one of Supplementary Notes 1 to 44, wherein the light receiving sub-mount (70) is formed in a triangular shape when viewed from a second direction intersecting the thickness direction and the first direction.

### Supplementary Note 46

The semiconductor light emitting device of any one of Supplementary Notes 1 to 44, wherein the light receiving sub-mount (70) is formed in a square shape when viewed from a second direction intersecting the thickness direction and the first direction.

### Supplementary Note 47

The semiconductor light emitting device of any one of Supplementary Notes 1 to 44, wherein the light receiving sub-mount (70) is formed in a rectangular shape when viewed from a second direction intersecting the thickness direction and the first direction.

The above description is merely exemplary. Those skilled in the art may recognize that many more possible combinations and replacements are adoptable beyond those listed for the purpose of describing the techniques of the present disclosure. The present disclosure is intended to cover all alternatives, variations, and modifications falling within the scope of the present disclosure including the claims.

While certain embodiments have been described, these embodiments have been presented by way of example only, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor light emitting device, comprising:
a substrate including a substrate front surface;
an edge light emitting element mounted on the substrate front surface, the edge light emitting element including a first element end surface facing a first direction intersecting a thickness direction perpendicular to the substrate front surface and a second element end surface facing an opposite direction to the first element end surface, the edge light emitting element configured such that light is emitted from the first element end surface and the second element end surface;
a light receiving sub-mount provided over the substrate front surface and including a mounting surface facing the second element end surface; and
a light receiving element mounted on the mounting surface and including a light receiving portion provided at a light receiving element front surface and facing the second element end surface.

2. The semiconductor light emitting device of claim 1, wherein the light receiving sub- mount has an insulation property.

3. The semiconductor light emitting device of claim 1, wherein the light receiving sub- mount is formed such that the mounting surface is perpendicular to the substrate front surface.

4. The semiconductor light emitting device of claim 1, wherein the light receiving sub- mount is formed such that the mounting surface extends away from the second element end surface as the mounting surface extends away from the substrate front surface in the thickness direction.

5. The semiconductor light emitting device of claim 4, wherein an angle of the mounting surface with respect to the substrate front surface is 60 degrees or more and less than 90 degrees.

6. The semiconductor light emitting device of claim 1, wherein the substrate includes a substrate back surface facing an opposite side to the substrate front surface,
wherein the semiconductor light emitting device further comprises a first back surface electrode and a second back surface electrode provided over the substrate back surface, and
wherein the light receiving element is electrically connected between the first back surface electrode and the second back surface electrode.

7. The semiconductor light emitting device of claim 6, wherein the light receiving element includes a first light receiving electrode provided over the light receiving element front surface, a light receiving element back surface facing an opposite side to the light receiving element front surface, and a second light receiving electrode provided over the light receiving element back surface.

8. The semiconductor light emitting device of claim 6, wherein the light receiving element includes a light receiving element back surface facing an opposite side to the light receiving element front surface, and a first light receiving electrode and a second light receiving electrode provided over the light receiving element back surface.

9. The semiconductor light emitting device of claim 7, wherein the light receiving sub- mount includes a first mounting electrode that is provided over the mounting surface and electrically connected to the first light receiving electrode, and a second mounting electrode that is provided over the mounting surface and electrically connected to the second light receiving electrode.

10. The semiconductor light emitting device of claim 9, further comprising:
a first front surface electrode provided over the substrate front surface and electrically connected to the first back surface electrode; and
a second front surface electrode provided over the substrate front surface and electrically connected to the second back surface electrode,
wherein the first mounting electrode is electrically connected to the first front surface electrode, and
wherein the second mounting electrode is electrically connected to the second front surface electrode.

11. The semiconductor light emitting device of claim 10, wherein the light receiving sub- mount is disposed to straddle the first front surface electrode and the second front surface electrode.

12. The semiconductor light emitting device of claim 10, wherein the light receiving sub- mount is disposed over the substrate front surface so as not to overlap with the first front surface electrode and the second front surface electrode when viewed from the thickness direction.

13. The semiconductor light emitting device of claim 10, further comprising:
a first wire configured to electrically connect the first light receiving electrode and the second mounting electrode.

14. The semiconductor light emitting device of claim 9, wherein the light receiving sub- mount is integrally formed with the substrate.

15. The semiconductor light emitting device of claim 14, further comprising:
a first internal wiring and a second internal wiring provided inside the light receiving sub-mount and the substrate,
wherein the first internal wiring is configured to electrically connect the first mounting electrode and the first back surface electrode, and
wherein the second internal wiring is configured to electrically connect the second mounting electrode and the second back surface electrode.

16. The semiconductor light emitting device of claim 1, further comprising:
a third front surface electrode provided over the substrate front surface; and
a fourth front surface electrode provided over the substrate front surface and spaced apart from the third front surface electrode,
wherein the edge light emitting element is electrically connected to the third front surface electrode.

17. The semiconductor light emitting device of claim 16, wherein the substrate includes a substrate back surface facing an opposite side to the substrate front surface, and further comprising:
a third back surface electrode provided over the substrate back surface and electrically connected to the third front surface electrode; and
a fourth back surface electrode provided over the substrate back surface and electrically connected to the fourth front surface electrode.

18. The semiconductor light emitting device of claim 16, wherein the edge light emitting element includes:
a light emitting element front surface facing a same direction as the substrate front surface;
a light emitting element back surface facing an opposite direction to the light emitting element front surface;
a first light emitting electrode formed over the light emitting element front surface; and
a second light emitting electrode formed over the light emitting element back surface,
wherein the second light emitting electrode is electrically connected to the third front surface electrode.

19. The semiconductor light emitting device of claim 18, further comprising:
a second wire configured to electrically connect the first light emitting electrode and the fourth front surface electrode.

20. The semiconductor light emitting device of claim 18, further comprising:
a light emitting sub-mount disposed over the third front surface electrode,
wherein the edge light emitting element is disposed over the light emitting sub-mount.
